(19) United States
(12) Patent Application Publication
(10) Pub. No.: US 2026/0095023 A1
(43) Pub. Date: Apr. 2, 2026

(54) SEMICONDUCTOR LIGHT EMITTING ELEMENT

(71) Applicant: HAMAMATSU PHOTONICS K.K., Hamamatsu-shi (JP)

(72) Inventors: Yoshitaka KUROSAKA, Shizuoka (JP); Tadataka EDAMURA, Shizuoka (JP); Masahiro HITAKA, Shizuoka (JP); Yutaka TAKAGI, Shizuoka (JP); Akio ITO, Shizuoka (JP)

(73) Assignee: HAMAMATSU PHOTONICS K.K., Hamamatsu-shi (JP)

(21) Appl. No.: 19/318,786

(22) Filed: Sep. 4, 2025

(30) Foreign Application Priority Data
Sep. 6, 2024 (JP) 2024-154093

(51) Int. Cl. H01S 5/026; H01S 5/042

(52) U.S. Cl. CPC H01S 5/026; H01S 5/04256

(57) ABSTRACT

A semiconductor light emitting element includes a semiconductor stack and an electrode portion. The semiconductor stack includes an active layer and a phase modulation layer. The phase modulation layer has a plurality of phase modulation regions. Each of the phase modulation regions includes a base region having a first refractive index, and a plurality of different refractive index regions that have a second refractive index different from the first refractive index and are distributed two-dimensionally. The electrode portion includes a plurality of electrodes that respectively overlap the plurality of phase modulation regions when viewed from the stacking direction of the semiconductor stack. The plurality of electrodes are electrically isolated from each other. Laser light resonated in each of the plurality of phase modulation regions is emitted through a second surface. The semiconductor light emitting element has a reflection reduction structure configured to reduce reflection of the light.

### CROSS-REFERENCE TO RELATED APPLICATIONS

Priority is claimed on Japanese Patent Application No. 2024-154093, filed Sep. 6, 2024, the entire content of which is incorporated herein by reference.

### TECHNICAL FIELD

The present disclosure relates to a semiconductor light emitting element.

### BACKGROUND

Japanese Unexamined Patent Publication No. 2023-131320 (hereinafter referred to as “Patent Document”) discloses a semiconductor light emitting element that can dynamically change an output optical image. This semiconductor light emitting element includes a semiconductor stack, a first electrode, and a second electrode. The semiconductor stack has a stacked structure including an active layer and a phase modulation layer between first and second surfaces. The phase modulation layer has a plurality of phase modulation regions that are arranged along a virtual plane perpendicular to a thickness direction of the phase modulation layer and optically coupled to each other. Each of the plurality of phase modulation regions includes a base region having a first refractive index and a plurality of different refractive index regions. The plurality of different refractive index regions are provided in the base region, have a second refractive index different from the first refractive index, and are distributed two-dimensionally along a plane thereof. The first electrode faces the first surface of the semiconductor stack. The second electrode faces the second surface of the semiconductor stack. One or both of the first and second electrodes include a plurality of electrode portions that respectively overlap the plurality of phase modulation regions when viewed from a stacking direction of the semiconductor stack. The plurality of electrode portions are electrically isolated from each other. Light output from the active layer resonates in each of the plurality of phase modulation regions of the phase modulation layer, and is formed as an optical image corresponding to arrangement of the plurality of different refractive index regions while being radiated from each of the plurality of phase modulation regions to a common irradiation region located in a direction intersecting both of the first and second surfaces of the semiconductor stack. The optical images output from each of the plurality of phase modulation regions are phase-locked to each other.

### SUMMARY

When the present inventors fabricated a prototype of the semiconductor light emitting element described in Patent Document, spot-like light of unknown origin unrelated to the intended optical image (hereinafter referred to as “stray light” in the present disclosure) was output from the semiconductor light emitting element together with the intended optical image. In order to output only the intended optical image from a semiconductor light emitting element, it is desirable to reduce such stray light. An object of the present disclosure is to provide a semiconductor light emitting element that can reduce stray light.

A semiconductor light emitting element according to an aspect of the present disclosure includes a semiconductor stack, a first electrode portion, and a second electrode portion. The semiconductor stack has a stacked structure between a first surface and a second surface. The stacked structure includes an active layer and a phase modulation layer. The phase modulation layer has a plurality of phase modulation regions. The plurality of phase modulation regions are arranged along a virtual plane perpendicular to a thickness direction of the phase modulation layer and optically coupled to each other. Each of the plurality of phase modulation regions includes a base region and a plurality of different refractive index regions. The base region has a first refractive index. The plurality of different refractive index regions are provided in the base region, have a second refractive index different from the first refractive index, and are distributed two-dimensionally along the virtual plane. The first electrode portion faces the first surface of the semiconductor stack. The second electrode portion faces the second surface of the semiconductor stack. One or both of the first electrode portion and the second electrode portion include a plurality of electrodes that respectively overlap the plurality of phase modulation regions when viewed from a stacking direction of the semiconductor stack. The plurality of electrodes are electrically isolated from each other. Light output from the active layer resonates along the virtual plane in each of the plurality of phase modulation regions of the phase modulation layer. The resonant light is radiated from each of the plurality of phase modulation regions via the second surface to an irradiation region located in a direction intersecting both the first surface and the second surface of the semiconductor stack. The semiconductor light emitting element has a reflection reduction structure configured to reduce reflection of the light emitted from each of the phase modulation regions at the first electrode portion.

According to the present disclosure, it is possible to provide a semiconductor light emitting element that can reduce stray light.

The present invention will be more fully understood from the detailed description given herein below and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a cross-sectional view of a stacked structure of a semiconductor light emitting element.

FIG. 2 is a plan view of a phase modulation layer (viewed from a thickness direction thereof).

FIG. 3 is an enlarged plan view showing a part of a phase modulation region.

FIG. 4 is an enlarged view showing one unit constituent region.

FIG. 5 is a diagram for describing coordinate conversion from spherical coordinates to coordinates in the XYZ Cartesian coordinate system.

FIG. 6 is an enlarged plan view showing a part of a coupling region.

FIG. 7 is a diagram schematically showing planar shapes of a first electrode portion and a second electrode portion, and a configuration for supplying an electric current to the first electrode portion and the second electrode portion.

FIG. 8A shows an electromagnetic field distribution in a resonance mode of symmetry A₁ at point M₁. FIG. 8B shows an electromagnetic field distribution in a resonance mode of B₂ symmetry at point M₁.

FIG. 9A shows an electromagnetic field distribution in a resonance mode of symmetry A₁ at point M₁. FIG. 9B shows an electromagnetic field distribution in a resonance mode of B₂ symmetry at point M₁.

FIG. 10 is a diagram conceptually showing an example of a plurality of optical images output from a plurality of phase modulation regions.

FIG. 11 is a diagram conceptually showing another example of a plurality of optical images output from the plurality of phase modulation regions.

FIG. 12 is a diagram conceptually showing yet another example of a plurality of optical images output from the plurality of phase modulation regions.

FIG. 13 is a diagram conceptually showing a first design method.

FIG. 14 is a diagram showing a phase modulation layer having four phase modulation regions in two columns in an X direction and two rows in a Y direction.

FIG. 15 is a diagram showing a phase modulation layer in which two phase modulation regions in a first row have phase distribution pattern B and two phase modulation regions in a second row have phase distribution pattern A.

FIG. 16 is a diagram conceptually showing a method for designing the phase distribution patterns A and B.

FIG. 17 is a diagram showing a phase modulation layer having m columns in the X direction and n rows in the Y direction, totaling m×n phase modulation regions.

FIG. 18 is a diagram conceptually showing a method for designing m×n phase distribution patterns.

FIG. 19 is a diagram conceptually showing a second design method.

FIG. 20 is a diagram conceptually showing a method for designing the phase distribution patterns A and B.

FIG. 21 is a diagram conceptually showing a method for designing m×n phase distribution patterns.

FIG. 22A is an image showing a far-field pattern observed in a prototyped semiconductor light emitting element. FIG. 22B is an image showing a far-field pattern observed in a semiconductor light emitting element provided with an InGaAs layer.

FIG. 23A and FIG. 23B are images showing the result of observing the vicinity of a contact layer of the semiconductor light emitting element using a Nomarski microscope.

FIG. 24 is a cross-sectional view showing a configuration of the semiconductor light emitting element disclosed in Patent Document that does not have a reflection reduction structure.

FIG. 25 is a diagram for describing the effect obtained by a semiconductor light emitting element according to a first embodiment.

FIG. 26 is a cross-sectional view showing a stacked structure of a semiconductor light emitting element according to a first modification.

FIG. 27 is a cross-sectional view showing a stacked structure of a semiconductor light emitting element according to a second modification.

FIG. 28 is a plan view of a cladding layer.

FIG. 29 is a cross-sectional view showing a configuration of a semiconductor light emitting element according to a third modification.

FIG. 30 is a plan view showing a phase modulation layer.

FIG. 31 is a partially enlarged plan view showing a phase shift region and a coupling region around the phase shift region.

FIG. 32 is an enlarged view of one unit constituent region.

FIG. 33 is a cross-sectional view showing a stacked structure of a semiconductor light emitting element according to a second embodiment.

FIG. 34 is a cross-sectional view showing a stacked structure of a semiconductor light emitting element according to a fifth modification.

FIG. 35 is a cross-sectional view showing a stacked structure of a semiconductor light emitting element according to a sixth modification.

FIG. 36 is a cross-sectional view showing a stacked structure of a semiconductor light emitting element according to a third embodiment.

### DETAILED DESCRIPTION

Specific examples of a semiconductor light emitting element of the present disclosure will be described below with reference to the drawings. Also, the present invention is not limited to these examples, is defined by the scope of the claims, and is intended to include all changes within the meaning and scope equivalent to the scope of the claims. In the following description, the same elements will be denoted by the same reference signs in the description of the drawings, and repeated descriptions thereof is omitted.

### First Embodiment

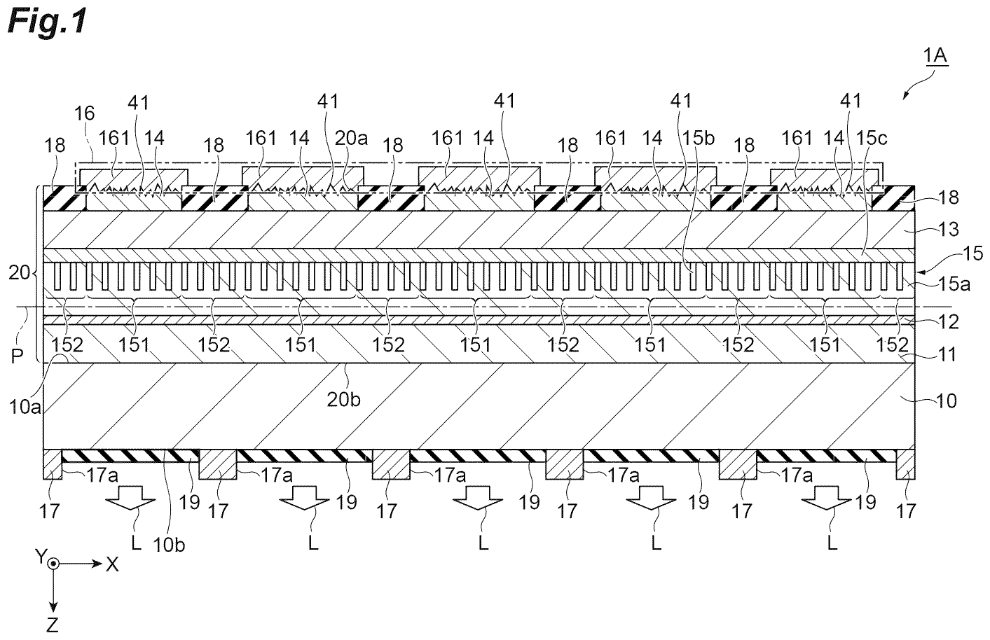

FIG. 1 is a cross-sectional view showing a stacked structure of a semiconductor light emitting element 1A of the present embodiment. In FIG. 1, the XYZ Cartesian coordinate system is defined in which an axis extending in a thickness direction of the semiconductor light emitting element 1A is set as a Z-axis. The semiconductor light emitting element 1A is a laser light source that forms a standing wave in an XY in-plane direction and outputs a phase-controlled plane wave in a direction intersecting the thickness direction. The semiconductor light emitting element 1A is an S-iPM laser and can output an optical image of any shape in a direction perpendicular to a main surface 10a of a semiconductor substrate 10, that is, the Z direction, or in a direction inclined with respect to the Z direction, or in a direction including both.

The semiconductor light emitting element 1A includes the semiconductor substrate 10. The semiconductor substrate 10 has the main surface 10a and a back surface 10b. The normal direction of the main surface 10a and the back surface 10b and the thickness direction of the semiconductor substrate 10 are along the Z direction. The semiconductor substrate 10 is composed of, for example, a compound semiconductor such as a GaAs-based semiconductor, an InP-based semiconductor, or a nitride-based semiconductor.

The semiconductor light emitting element 1A further includes a semiconductor stack 20. The semiconductor stack 20 is provided on the main surface 10a of the semiconductor substrate 10. A stacking direction of the semiconductor stack 20 is along the Z direction. The semiconductor stack 20 has a stacked structure including, between a first surface 20a and a second surface 20b, a cladding layer 11, an active layer 12, a cladding layer 13, a contact layer 14, and a phase modulation layer 15. The second surface 20b of the semiconductor stack 20 faces the main surface 10a of the semiconductor substrate 10. In the illustrated example, the cladding layer 11 is provided on the main surface 10a of the semiconductor substrate 10, the active layer 12 is provided on the cladding layer 11, the phase modulation layer 15 is provided on the active layer 12, the cladding layer 13 is provided on the phase modulation layer 15, and the contact layer 14 is provided on the cladding layer 13. That is, the cladding layer 11 is provided between the active layer 12 and the second surface 20b, the cladding layer 13 is provided between the active layer 12 and the first surface 20a, and the cladding layers 11 and 13 sandwich the active layer 12 and the phase modulation layer 15. Also, in the illustrated example, the phase modulation layer 15 is provided between the active layer 12 and the cladding layer 13, but the phase modulation layer 15 may be provided between the cladding layer 11 and the active layer 12. A light guide layer may be provided in at least one of a space between the active layer 12 and the cladding layer 13 and a space between the active layer 12 and the cladding layer 11, if required. The light guide layer may include a carrier barrier layer for efficiently confining carriers in the active layer 12.

The cladding layer 11, the active layer 12, the cladding layer 13, and the contact layer 14 are composed of, for example, compound semiconductors such as GaAs-based semiconductors, InP-based semiconductors, or nitride-based semiconductors. The active layer 12 has, for example, a multiple quantum well structure. The energy bandgaps of the cladding layers 11 and 13 are larger than an energy bandgap of the active layer 12. The thickness direction of the cladding layer 11, the active layer 12, the cladding layer 13, and the contact layer 14 coincides with the Z-axis direction.

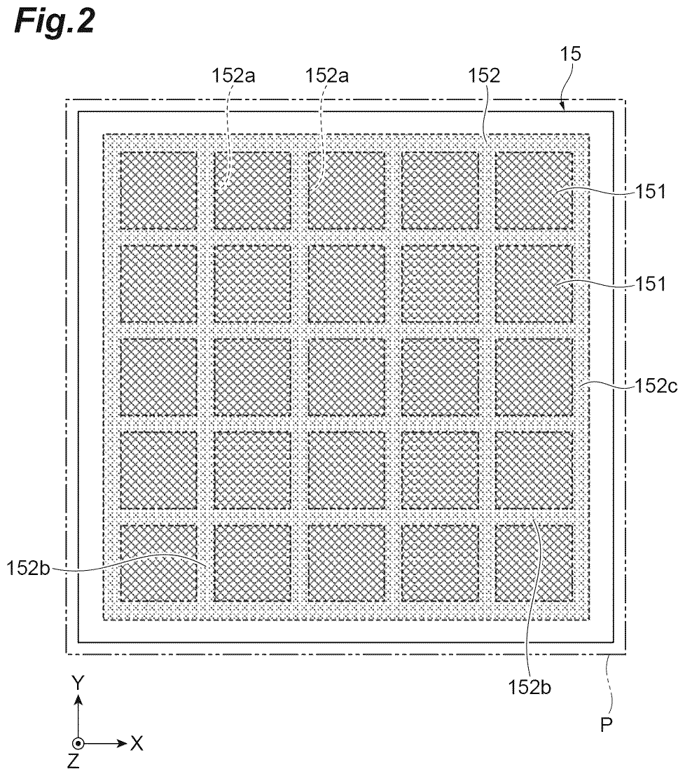

The phase modulation layer 15 is optically coupled to the active layer 12. A thickness direction of the phase modulation layer 15 coincides with the Z-axis direction. FIG. 2 is a plan view (viewed from the thickness direction) of the phase modulation layer 15. As shown in FIGS. 1 and 2, the phase modulation layer 15 has a plurality of phase modulation regions 151 and a coupling region 152. The planar shape of the coupling region 152 viewed from the stacking direction of the semiconductor stack 20 is, for example, a lattice shape. Each of the plurality of phase modulation regions 151 is provided in a respective one of a plurality of openings 152a of the coupling region 152 formed in a lattice shape.

The planar shape of each of the plurality of phase modulation regions 151 is, for example, a square or a rectangle. The plurality of phase modulation regions 151 are two-dimensionally arranged along a virtual plane P perpendicular to the thickness direction of the phase modulation layer 15 (in other words, parallel to the XY plane) and optically coupled to each other. In the illustrated example, the plurality of phase modulation regions 151 are arranged along the X direction and the Y direction. Also, in the illustrated example, the plurality of phase modulation regions 151 are arranged two-dimensionally, but the plurality of phase modulation regions 151 may be arranged one-dimensionally. In the illustrated example, the plurality of phase modulation regions 151 are provided spaced apart from each other. The coupling region 152 includes portions 152b provided between the phase modulation regions 151 adjacent to each other and outer frame-shaped portion 152c that collectively surrounds the plurality of phase modulation regions 151.

As shown in FIG. 1, each of the plurality of phase modulation regions 151 is configured to include a base region 15a and a plurality of different refractive index regions 15b. Similarly, the coupling region 152 is also configured to include the base region 15a and the plurality of different refractive index regions 15b. The base region 15a is formed of a first refractive index medium. The base region 15a is formed of a compound semiconductor such as a GaAs-based semiconductor, an InP-based semiconductor, or a nitride-based semiconductor. The plurality of different refractive index regions 15b are made of a second refractive index medium having a different refractive index from the first refractive index medium, and are present in the base region 15a. The different refractive index regions 15b are, for example, cavities. The different refractive index regions 15b are covered by a cap region 15c provided on the base region 15a. The cap region 15c forms a part of the phase modulation layer 15, and is formed of, for example, the same material as the base region 15a.

The plurality of different refractive index regions 15b are distributed two-dimensionally along the virtual plane P. In each of the phase modulation regions 151, the plurality of different refractive index regions 15b include a lattice-shaped, approximately periodic structure. When an equivalent refractive index of a mode is defined as n and a lattice spacing is defined as a, a wavelength λ₀ selected by each of the phase modulation regions 151 is expressed as λ₀=(√2)a×n in the case of M₁ point oscillation, for example. This wavelength λ₀ is included in an emission wavelength range of the active layer 12. Each of the phase modulation regions 151 can select a band edge wavelength near the wavelength λ₀ among emission wavelengths of the active layer 12 and output it to the outside. The light incident on each of the phase modulation regions 151 from the active layer 12 forms a predetermined mode in each of the phase modulation regions 151 in accordance with the arrangement of the different refractive index regions 15b, and is output as laser light L from the back surface 10b of the semiconductor substrate 10 through the second surface 20b to the outside of the semiconductor light emitting element 1A.

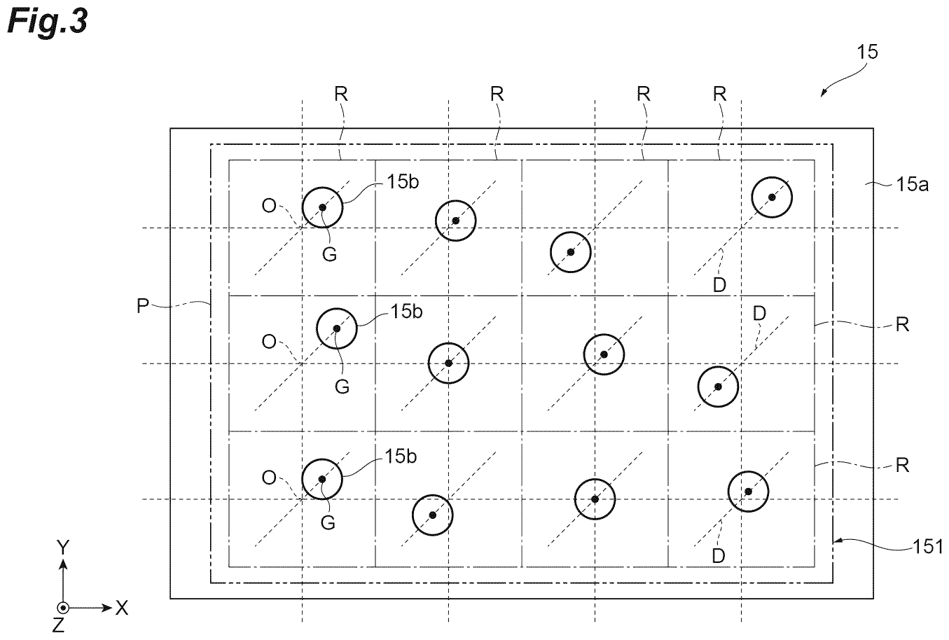

FIG. 3 is an enlarged plan view showing a part of the phase modulation region 151. Although only one phase modulation region 151 is shown in FIG. 3, the configurations of the other phase modulation regions 151 are also the same. As described above, the phase modulation region 151 includes the base region 15a and the plurality of different refractive index regions 15b. In FIG. 3, a virtual square lattice along the virtual plane P is set for the phase modulation region 151. One side of the square lattice is parallel to the X-axis and the other side is parallel to the Y-axis. Square-shaped unit constituent regions R with their centers at lattice points O in the square lattice are arranged two-dimensionally across a plurality of columns along the X-axis and a plurality of rows along the Y-axis. XY coordinates of each of the unit constituent regions R are defined by a position of centroid of each of the unit constituent regions R. These positions of centroid coincide with the lattice points O of the virtual square lattice. For example, one different refractive index region 15b is provided in each of the unit constituent regions R. The planar shape of the different refractive index region 15b is, for example, a circular shape. The lattice point O may be located outside the different refractive index region 15b, or may be located inside the different refractive index region 15b.

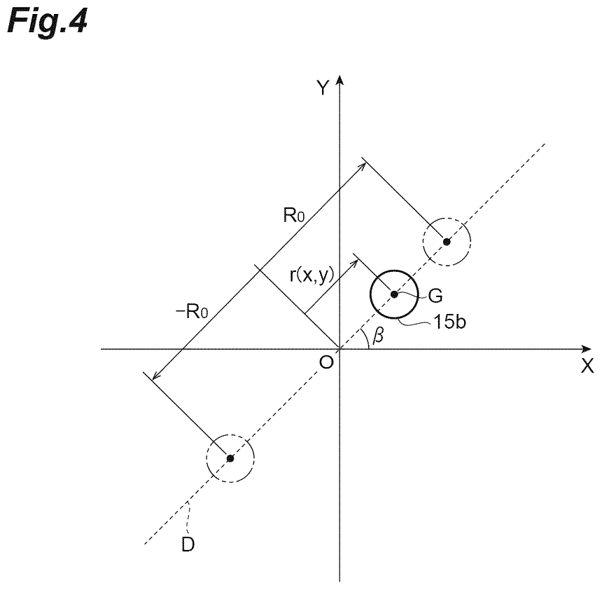

FIG. 4 is an enlarged view of one unit constituent region R. As shown in the figure, each different refractive index region 15b has a centroid G. The centroid G of the different refractive index region 15b is disposed on a straight line D set for each lattice point O. The straight line D passes through the lattice point O corresponding to each unit constituent region R and is inclined with respect to each side of the square lattice. That is, the straight line D is a straight line inclined with respect to both the X-axis and Y-axis. An inclination angle of the straight line D with respect to one side of the square lattice, in other words, the X-axis, is β.

The inclination angle β is the same for all straight lines D in the phase modulation region 151. Also, the inclination angle β is the same among the plurality of phase modulation regions 151. The inclination angle β satisfies 0°<β<90°, and in one example, β=45°. Alternatively, the inclination angle β satisfies 180°<β<270°, and in one example, β=225°. If the inclination angle β satisfies 0°<β<90° or 180°<β<270°, the straight line D extends from a first quadrant to a third quadrant of a coordinate plane defined by the X-axis and the Y-axis. The inclination angle β satisfies 90°<β<180°, and in one example, β=135°. Alternatively, the inclination angle β satisfies 270°<β<360°, and in one example, β=315°. If the inclination angle R satisfies 90°<β<180° or 270°<β<360°, the straight line D extends across a second quadrant and a fourth quadrant of the coordinate plane defined by the X-axis and the Y-axis. Thus, the inclination angle β is an angle other than 0°, 90°, 180°, and 270°.

Here, a distance between the lattice point O and the centroid G is defined as r(x, y). x is a position of the x-th lattice point on the X-axis and y is a position of the y-th lattice point on the Y-axis. If the distance r(x, y) is a positive value, the centroid G is located in the first or second quadrant. If the distance r(x, y) is a negative value, the centroid G is located in the third quadrant or the fourth quadrant. When the distance r(x, y) is 0, the lattice point O and the centroid G coincide with each other. The inclination angle is preferably 45°, 135°, 225°, or 315°. In the case of these inclination angles, only two of four wave vectors that form a standing wave at point M, for example, in-plane wave vectors (±π/a, ±π/a), are phase modulated, and the other two are not phase modulated. Accordingly, a stable standing wave can be formed.

The distance r(x, y) is set individually for each different refractive index region 15b in accordance with a phase distribution φ(x, y) corresponding to an optical image to be output from each phase modulation region 151. That is, if a phase φ(x, y) at certain coordinates (x, y) is φ₀, the distance r(x, y) is set to 0. If the phase φ(x, y) is π+φ₀, the distance r(x, y) is set to the maximum value R₀. If the phase φ(x, y) is −π+φ₀, the distance r(x, y) is set to the minimum value −R₀. In addition, for an intermediate phase φ(x, y) therebetween, the distance r(x, y) is set so that r(x, y)={φ(x, y)−φ₀}×R₀/π. When the lattice spacing of the virtual square lattice is defined as a, the maximum value R₀ of r(x, y) is, for example, within the range of the following equation (1).

$$\begin{matrix}[ Equation 1 ] & \\ 0 \leq {R}_{0} \leq \frac{a}{\sqrt{2}} & ( 1 )\end{matrix}$$

An initial phase go can be set arbitrarily. The phase distribution φ(x, y) and distribution of the distance r(x, y) have specific values for each position determined by values of x and y, but are not necessarily represented by specific functions.

By determining the distribution of the distance r(x, y) of the different refractive index regions 15b in each of the plurality of phase modulation regions 151, it is possible to output a desired optical image from each of the plurality of phase modulation regions 151. Each of the phase modulation regions 151 is configured to satisfy the following conditions

As a first precondition, the virtual square lattice having a square shape configured of M₁×N₁ unit constituent regions R is set on the XY plane. M₁ and N₁ are integers of 1 or more.

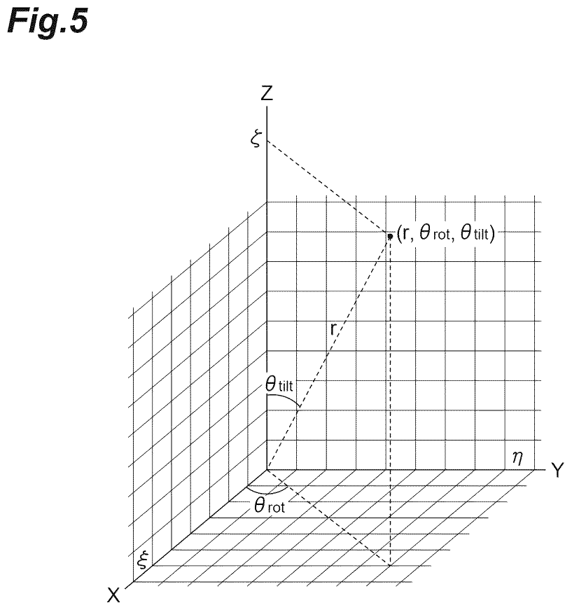

As shown in FIG. 5, spherical coordinates (r, θᵣₒₜ, θₜᵢₗₜ) are defined by a length r of a radius vector, a tilt angle θₜᵢₗₜ from the Z-axis, and a rotation angle θᵣₒₜ from the X-axis specified on the XY plane. As a second precondition, coordinates (ξ, η, ζ) in the XYZ Cartesian coordinate system are assumed to satisfy correlations shown in the following equations (2) to (4) for the spherical coordinates (r, θᵣₒₜ, θₜᵢₗₜ). FIG. 5 is a diagram for describing coordinate conversion from the spherical coordinates (r, θᵣₒₜ, θₜᵢₗₜ) to the coordinates (ξ, η, ζ) in the XYZ Cartesian coordinate system. The coordinates (ξ, η, λ) represent a designed optical image on a predetermined plane set in the XYZ Cartesian coordinate system, which is a real space.

$$\begin{matrix}[ Equation 2 ] & \\ ξ = r sin {θ}_{tilt} cos {θ}_{rot} & ( 2 )\end{matrix}$$

$$\begin{matrix}[ Equation 3 ] & \\ η = r sin {θ}_{tilt} sin {θ}_{rot} & ( 3 )\end{matrix}$$

$$\begin{matrix}[ Equation 4 ] & \\ ζ = r cos {θ}_{tilt} & ( 4 )\end{matrix}$$

The light emitted from each phase modulation region 151 is assumed to be a set of bright spots that are directed in a direction defined by the angles θₜᵢₗₜ and θᵣₒₜ. In this case, the angles θₜᵢₗₜ and θᵣₒₜ are assumed to be converted to coordinate values kx and ky. The coordinate value kx is a normalized wave number defined by the following equation (5), and is a coordinate value on a Kₓ axis corresponding to the X-axis. The coordinate value ky is a normalized wave number defined by the following equation (6), and is a coordinate value on a K_{Y-axis} corresponding to the Y-axis and perpendicular to the Kₓ axis. A normalized wave number means a wave number normalized with the wave number 2π/a set to 1.0, which corresponds to a lattice spacing of a virtual square lattice. In this case, in a wave number space defined by the Kₓ axis and the K_{Y-axis}, a specific wave number range including a beam pattern corresponding to an optical image is configured by M₂×N₂ image regions FR, each of which has a square shape. M₂ and N₂ are integers of 1 or more. The integer M₂ does not have to be equal to the integer M₁. The integer N₂ does not have to match the integer N₁. The equations (5) and (6) are disclosed, for example, in the following non-patent document.

Y. Kurosaka et al., “Effects of non-lasing band in two-dimensional photonic-crystal lasers clarified using omnidirectional band structure,” Opt. Express 20, 21773-21783 (2012)

$$\begin{matrix}[ Equation 5 ] & \\ {k}_{x} = \frac{a}{λ} sin {θ}_{tilt} cos {θ}_{rot} & ( 5 )\end{matrix}$$

$$\begin{matrix}[ Equation 6 ] & \\ {k}_{y} = \frac{a}{λ} sin {θ}_{tilt} sin {θ}_{rot} & ( 6 )\end{matrix}$$

a: Lattice constant of virtual square lattice
λ: Oscillation wavelength of semiconductor light emitting element 1A

In the wave number space, the image region FR(kx, ky) is specified by a coordinate component kx in the Kₓ-axis direction and a coordinate component ky in the K_{y}-axis direction. The coordinate component kx is an integer from 0 to M₂−1. The coordinate component ky is an integer from 0 to N₂−1. The unit constituent region R(x, y) on the XY plane is specified by a coordinate component x in the X-axis direction and a coordinate component y in the Y-axis direction. The coordinate component x is an integer from 0 to M₁−1. The coordinate component y is an integer from 0 to N₁−1. As a third precondition, a complex amplitude CA(x, y) obtained by performing two-dimensional inverse discrete Fourier transform of each of the image regions FR(kx, ky) into the unit constituent region R(x, y) is given by the following equation (7), where j is an imaginary unit. The complex amplitude CA(x, y) is given by the following equation (8) where an amplitude term is A(x, y) and a phase term is φ(x, y). As a fourth precondition, the unit constituent region R(x, y) is defined by a s axis and a t axis. The s axis and the t axis are respectively parallel to the X-axis and the Y-axis and orthogonal to each other at the lattice point O(x, y) serving as the center of the unit constituent region R(x, y).

$$\begin{matrix}[ Equation 7 ] & \\ CA ( x , y ) = {\sum }_{{k}_{x} = 0}^{M 2 - 1} {\sum }_{{k}_{y} = 0}^{N 2 - 1} F R ( {k}_{x} , {k}_{y} ) exp [ j 2 π ( \frac{{k}_{x}}{M 2} x + \frac{{k}_{y}}{N 2} y ) ] & ( 7 )\end{matrix}$$

$$\begin{matrix}[ Equation 8 ] & \\ CA ( x , y ) = A ( x , y ) \times exp [ j ϕ ( x , y ) ] & ( 8 )\end{matrix}$$

Under the first to fourth preconditions described above, each phase modulation region 151 is configured to satisfy the following conditions. That is, the corresponding different refractive index region 15b is disposed in the unit constituent region R(x, y) so that the distance r(x, y) from the lattice point O (x, y) to the centroid G of the corresponding different refractive index region 15b satisfies the following relationship.

$$r ( x , y ) = C \times ( φ ( x , y ) - {φ}_{0} )$$

C: Proportionality constant, for example, R₀/π
φ₀: Arbitrary constant, for example, 0

When a desired optical image is to be obtained, the optical image may be subjected to inverse Fourier transform, and a distribution of distance r(x, y) in accordance with the phase φ(x, y) of the complex amplitude may be given to the plurality of different refractive index regions 15b. The phase φ(x, y) and the distance r(x, y) may be proportional to each other.

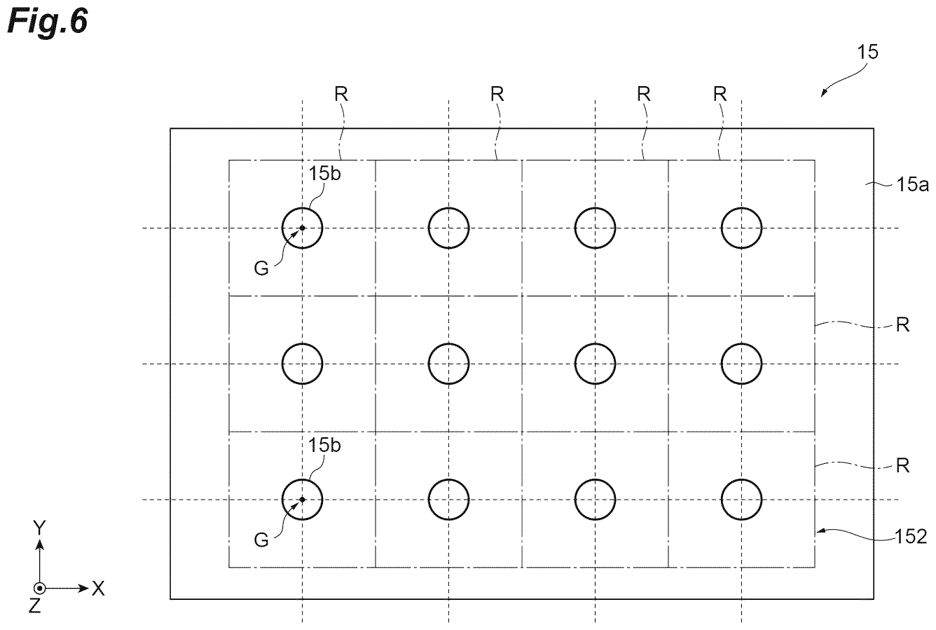

FIG. 6 is an enlarged plan view showing a part of the coupling region 152. Although FIG. 6 shows only a part of the coupling region 152, configurations of other parts of the coupling region 152 are also the same. As described above, the coupling region 152 also includes the base region 15a and the plurality of different refractive index regions 15b. In the coupling region 152, the same virtual square lattice as that in FIG. 3 is set. One side of the square lattice is parallel to the X-axis and the other side is parallel to the Y-axis. The lattice constant a of the square lattice is equal to a lattice constant a of the square lattice of the phase modulation region 151. In the coupling region 152, the centroids G of the plurality of different refractive index regions 15b are located on the lattice points of the square lattice. In other words, positions of the centroids G of the plurality of different refractive index regions 15b coincide with positions of the lattice points of the square lattice. Accordingly, in the coupling region 152, the plurality of different refractive index regions 15b are periodically arranged along the X-axis and the Y-axis.

Reference is again made to FIG. 1. The semiconductor light emitting element 1A further includes an electrode portion 16 (first electrode portion) and an electrode portion 17 (second electrode portion). The electrode portion 16 is provided to face the first surface 20a of the semiconductor stack 20, and in the illustrated example, the electrode portion 16 is provided on the first surface 20a, that is, on the contact layer 14. The electrode portion 16 forms ohmic contact with the contact layer 14. The electrode portion 17 is provided to face the second surface 20b of the semiconductor stack 20, and in the illustrated example, the electrode portion 17 is provided on the back surface 10b of the semiconductor substrate 10. The electrode portion 17 forms ohmic contact with the semiconductor substrate 10. As a typical shape, an electrode 161 (described later) of the electrode portion 16 has a square shape with a side length in the range of 50 μm to 500 μm, or a perfect circular shape with a diameter in the range of 50 μm to 500 μm. Also, the electrode portion 17 is an aperture electrode whose opening has a square shape with a side length in the range of 50 μm to 500 μm.

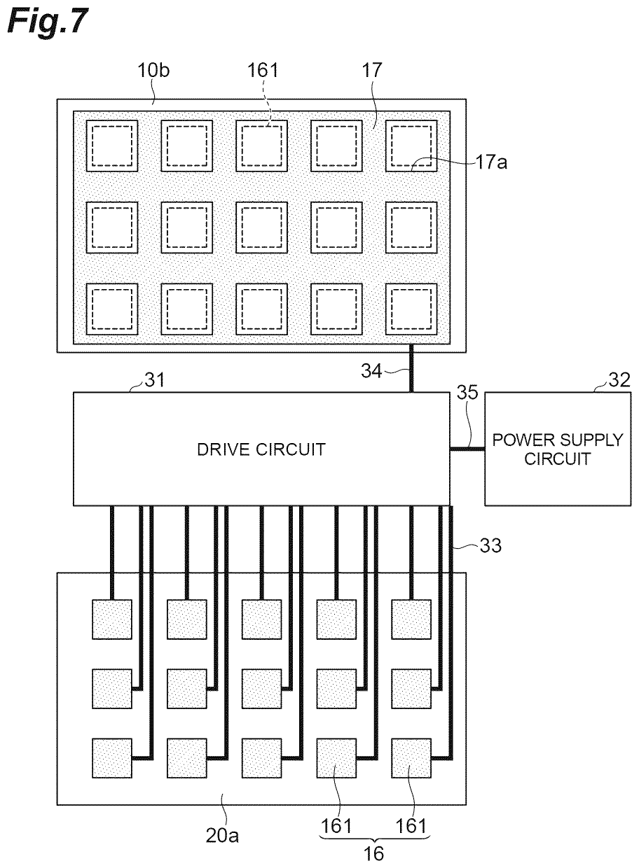

FIG. 7 is a diagram schematically showing planar shapes of the electrode portions 16 and 17 and a configuration for supplying an electric current to the electrode portions 16 and 17. As shown in FIG. 7, the electrode portion 17 has a plurality of openings 17a. Each opening 17a corresponds one-to-one to each phase modulation region 151. When viewed from the thickness direction of the semiconductor stack 20, the opening 17a overlaps the corresponding phase modulation region 151. The planar shape of each opening 17a is, for example, a square or a rectangle. The electrode portion 16 includes a plurality of electrodes 161. The plurality of electrodes 161 are arranged with gaps between them and are electrically isolated from each other. Also, the electrical separation of the electrodes from each other means that there is no other path for electrical connection except for the path through the semiconductor stack 20. Each electrode 161 corresponds one-to-one to each phase modulation region 151. When viewed from the thickness direction of the semiconductor stack 20, the electrode 161 overlaps the corresponding phase modulation region 151. The planar shape of each electrode 161 is, for example, a square or a rectangle.

Each of the plurality of electrodes 161 is individually and electrically connected to a drive circuit 31 via a respective wiring 33. Also, the electrode portion 17 is electrically connected to the drive circuit 31 via a wiring 34. The drive circuit 31 is electrically connected to a power supply circuit 32 via a wiring 35. The drive circuit 31 receives power supply from the power supply circuit 32 and supplies a drive current between the plurality of electrodes 161 and the electrode portion 17. The drive circuit 31 can freely vary a magnitude of the drive current for each electrode 161. The magnitude of the drive current to each electrode 161 is set independently for each electrode 161.

Reference is again made to FIG. 1. Portions of the contact layer 14 except for the portions overlapping each electrode 161 are removed by etching to limit a current path. Accordingly, the contact layer 14 is divided into a plurality of portions respectively corresponding to the plurality of electrodes 161. Gaps between the plurality of portions of the contact layer 14 are filled with a protective film 18. Thus, the surface of the semiconductor stack 20 exposed from the electrode portion 16 is protected. For example, the protective film 18 is formed of an inorganic insulator such as silicon nitride (for example, SiN) or silicon oxide (for example, SiO₂). Also, the portions of the contact layer 14 except for the portions overlapping each electrode 161 may remain without being removed. In that case, the protective film 18 is provided on the contact layer 14 in the gaps between the plurality of electrodes 161.

Regions of the back surface 10b of the semiconductor substrate 10 except for the region in which the electrode portion 17 is provided are covered with an antireflection film 19 including insides of the openings 17a. The antireflection film 19 in other regions except for the openings 17a may be removed. The antireflection film 19 is composed of a single layer or multilayer made of a dielectric material such as silicon nitride (for example, SiN) or silicon oxide (for example, SiO₂). For the dielectric multilayer film, for example, a film formed by laminating two or more types of dielectric layers selected from a group of dielectric layers formed of titanium oxide (TiO₂), silicon dioxide (SiO₂), silicon monoxide (SiO), niobium oxide (Nb₂O₅), tantalum pentoxide (Ta₂O₅), magnesium fluoride (MgF₂), titanium oxide (TiO₂), aluminum oxide (Al₂O₃), cerium oxide (CeO₂), indium oxide (In₂O₃), and zirconium oxide (ZrO₂) can be used. The dielectric multilayer film is formed, for example, by laminating a plurality of films each having an optical film thickness of λ/4 for light of wavelength λ.

Also, in the present embodiment, the electrode portion 16 facing the first surface 20a includes the plurality of electrodes 161, but alternatively, or in addition to this configuration, the electrode portion 17 facing the second surface 20b may include a plurality of electrodes. In this case, like the plurality of electrodes 161, the plurality of electrodes of the electrode portion 17 are also arranged with gaps between them and are electrically isolated from each other. Each electrode of the electrode portion 17 corresponds one-to-one to each phase modulation region 151. When viewed from the thickness direction of the semiconductor stack 20, each electrode of the electrode portion 17 overlaps the corresponding phase modulation region 151. The planar shape of each electrode of the electrode portion 17 is, for example, a rectangular frame shape including the openings 17a. Each of the plurality of electrodes of the electrode portion 17 is electrically connected individually to the drive circuit 31 via a respective one of the plurality of wires. The drive circuit 31 freely adjusts the magnitude of the drive current for each electrode of the electrode portion 17.

The semiconductor light emitting element 1A has a plurality of reflection reduction structures 41. Each reflection reduction structure 41 is configured to reduce reflection of light emitted from each phase modulation region 151 at the electrode portion 16. The reflection reduction structure 41 of the present embodiment includes a structure that scatters the light from the phase modulation region 151 to the electrode portion 16. The scattering structure is provided between the electrode portion 16 and both the active layer 12 and the phase modulation layer 15, and overlaps the plurality of phase modulation regions 151 when viewed from the stacking direction of the semiconductor stack 20. For example, the scattering structure includes an uneven structure formed on the surface of the contact layer 14, that is, the first surface 20a. The uneven structure is, for example, caused by lattice mismatch in the semiconductor stack 20, especially in the layers above both the active layer 12 and the phase modulation layer 15. Alternatively, the uneven structure is formed by roughening the first surface 20a using, for example, sandpaper or the like. In that case, a surface roughness (RMS value) of the first surface 20a is in the range of 30 nm to 50 nm, for example.

In the semiconductor light emitting element 1A, when a drive current is supplied between the electrode 161 and the electrode portion 17, recombination of electrons and holes occurs in the portion of the active layer 12 located directly under the electrode 161, and light is output from that portion of the active layer 12. In this case, electrons and holes that contribute to the light emission, as well as the light output from the active layer 12, are efficiently confined between the cladding layer 11 and the cladding layer 13.

The light output from that portion of the active layer 12 enters the phase modulation region 151 facing that portion. Then, the light resonates along the virtual plane P in the phase modulation region 151, forming a predetermined mode in accordance with the arrangement of the plurality of different refractive index regions 15b. Some of the laser light L output from the phase modulation region 151 is directly output from the back surface 10b through the openings 17a to the outside of the semiconductor light emitting element 1A. In this case, a signal light contained in the laser light L is emitted in a direction intersecting both the first surface 20a and the second surface 20b of the semiconductor stack 20. In other words, the signal light contained in the laser light L is emitted in any direction including a direction perpendicular to the back surface 10b and a direction inclined with respect to the direction perpendicular to the back surface 10b. It is the signal light that constitutes the emitted light from the semiconductor light emitting element 1A. The signal light is mainly the 1st order diffracted light or the −1st order diffracted light of the laser light, or both. Hereinafter, the 1st order diffracted light is referred to as the 1st order light, and the −1st order diffracted light is referred to as the −1st order light. The rest of the laser light L output from the phase modulation region 151 is scattered by the reflection reduction structure 41.

The laser light L output from each of the plurality of phase modulation regions 151 is projected as an optical image corresponding to the arrangement of the plurality of different refractive index regions 15b in a common irradiation region (far field) located in a direction intersecting both the first surface 20a and the second surface 20b of the semiconductor stack 20. The plurality of different refractive index regions 15b in at least two of the plurality of phase modulation regions 151 have different arrangements for each phase modulation region 151. Accordingly, a plurality of optical images respectively output from the plurality of phase modulation regions 151 interfere with each other to form a final optical image.

In order to obtain the final optical image by causing the plurality of optical images respectively output from the plurality of phase modulation regions 151 to interfere with each other, these optical images are phase-locked to each other. In order to cause these optical images to be phase-locked to each other, in the present embodiment, the coupling region 152 is provided between the phase modulation regions 151 adjacent to each other. Since resonance modes of the phase modulation regions 151 adjacent to each other are shared through the coupling region 152, the phase of the laser light L resonating in each of the phase modulation regions 151 can be synchronized among the plurality of phase modulation regions 151. Also, the coupling region 152 may be eliminated, and adjacent phase modulation regions 151 may be adjoined. Even in such a case, the phase of the laser light L resonating in each of the phase modulation regions 151 can be synchronized among the plurality of phase modulation regions 151. In addition, in order to cause the plurality of optical images to be phase-locked to each other, it is also required to consider phase synchronization when the phase distribution φ(x, y) of each of the phase modulation regions 151 is designed. The design of the phase distribution φ(x, y) in consideration of phase synchronization will be described later.

Also, in order to obtain a desired optical image by causing the optical images respectively output from the plurality of phase modulation regions 151 to interfere with each other, it is desirable that polarization directions of these optical images be aligned with each other. In the present embodiment, the centroid G of the different refractive index region 15b is located on the straight line D set for each lattice point O. In addition, the inclination angle R of the straight line D is the same at all lattice points O in the phase modulation region 151, and is also the same among the plurality of phase modulation regions 151.

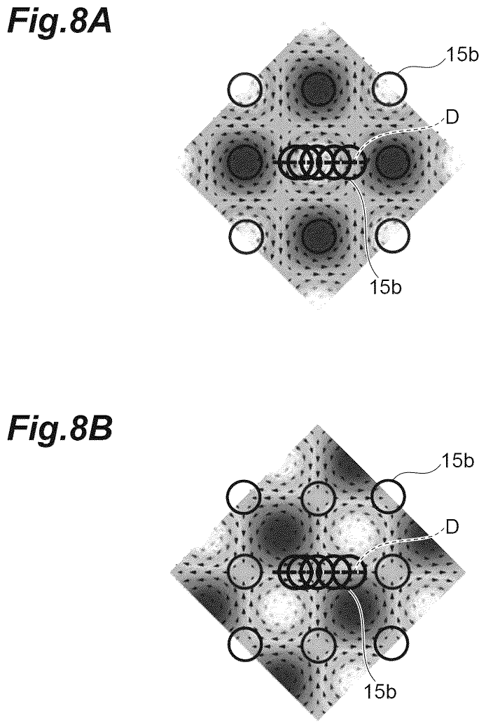

Here, FIGS. 8A and 8B are diagrams each showing an electromagnetic field distribution in the phase modulation region 151. FIG. 8A shows an electromagnetic field distribution in a resonance mode of symmetry A₁ at point M₁. FIG. 8B shows an electromagnetic field distribution in a resonance mode of B₂ symmetry at point M₁. In FIGS. 8A and 8B, arrows represent magnitudes and directions of an electric field, and color shades represent magnitudes of a magnetic field. In the present embodiment, the centroid G of the different refractive index region 15b is located on the straight line D. FIGS. 8A and 8B schematically show a change in arrangement of the central different refractive index region 15b. In that case, in any electromagnetic field distribution, the polarization directions are expected to be aligned regardless of the distance between the centroid G of the different refractive index region 15b and the lattice point O, in other words, regardless of phase values realized by each different refractive index region 15b.

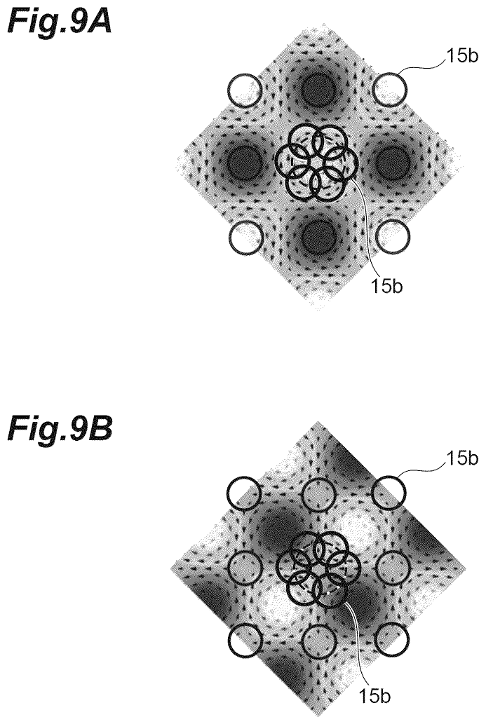

On the other hand, each of FIGS. 9A and 9B shows, as a comparative example, an electromagnetic field distribution when the centroid G of the different refractive index region 15b is located at a fixed distance from the lattice point O and an azimuth angle (rotation angle) around the lattice point O of a vector connecting the lattice point O to the centroid G is set for each different refractive index region 15b in accordance with the phase distribution φ(x, y). In this example, FIG. 9A shows an electromagnetic field distribution in a resonance mode of symmetry A₁ at point M₁. FIG. 9B shows an electromagnetic field distribution in a resonance mode of B₂ symmetry at point M₁. In FIGS. 9A and 9B, arrows also indicate magnitudes and directions of an electric field, and color shades indicate magnitudes of a magnetic field. In this comparative example, in any electromagnetic field distribution, the polarization direction changes in accordance with the rotation angle around the lattice point O of the different refractive index region 15b. Accordingly, it is almost impossible to expect the polarization directions to be aligned. For these reasons, as in the present embodiment, a form in which the centroid G of the different refractive index region 15b is disposed on the straight line D and the distance between the centroid G and the lattice point O changes depending on the phase is desirable.

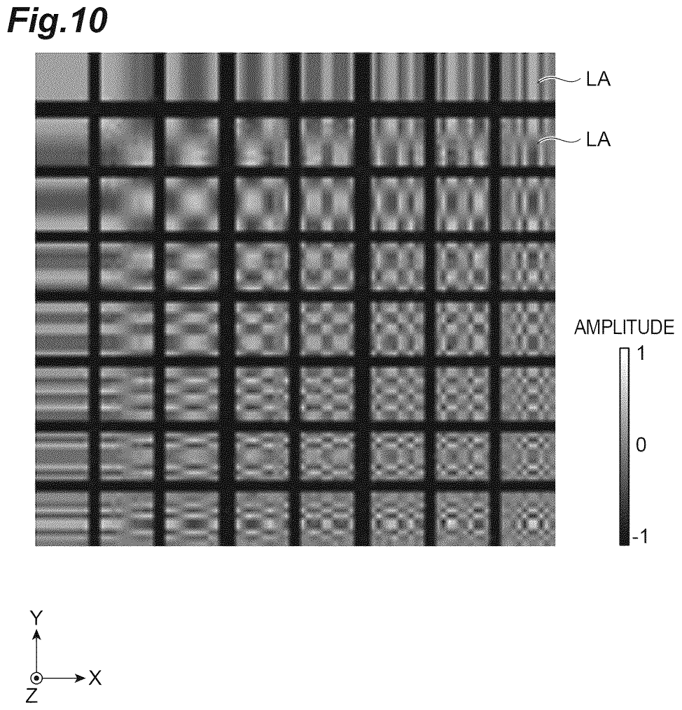

As described above, the semiconductor light emitting element 1A in the present embodiment irradiates the common irradiation region with the plurality of optical images output from the plurality of phase modulation regions 151. Then, the plurality of optical images are superimposed to interfere with each other to form a final optical image (hologram). FIG. 10 is a diagram conceptually showing an example of the plurality of optical images output from the plurality of phase modulation regions 151. FIG. 10 shows a total of 64 optical images LA arranged in 8 columns in the X direction and 8 rows in the Y direction, in which a lower light intensity is shown darker, and a higher light intensity is shown lighter. These are optical images output from each of a total of 64 phase modulation regions 151 arranged in 8 columns in the X direction and 8 rows in the Y direction. In this example, a light intensity distribution of the optical image LA output from each of the plurality of phase modulation regions 151 includes a sinusoidal distribution. In the sinusoidal distribution, the periods in two mutually orthogonal directions (X and Y directions) vary for each phase modulation region 151. Such an optical image LA can be used, for example, as a base image of discrete cosine transform (DCT). That is, by performing the discrete cosine transform on the light intensity distribution of the target final optical image and outputting the obtained plurality of base images respectively from the plurality of phase modulation regions 151, the final optical image can be achieved. In addition, by changing the magnitude of the drive current of the plurality of electrodes 161 respectively corresponding to the plurality of phase modulation regions 151, a degree of contribution of each base image to the final optical image can be individually adjusted to present a dynamic optical image that changes over time.

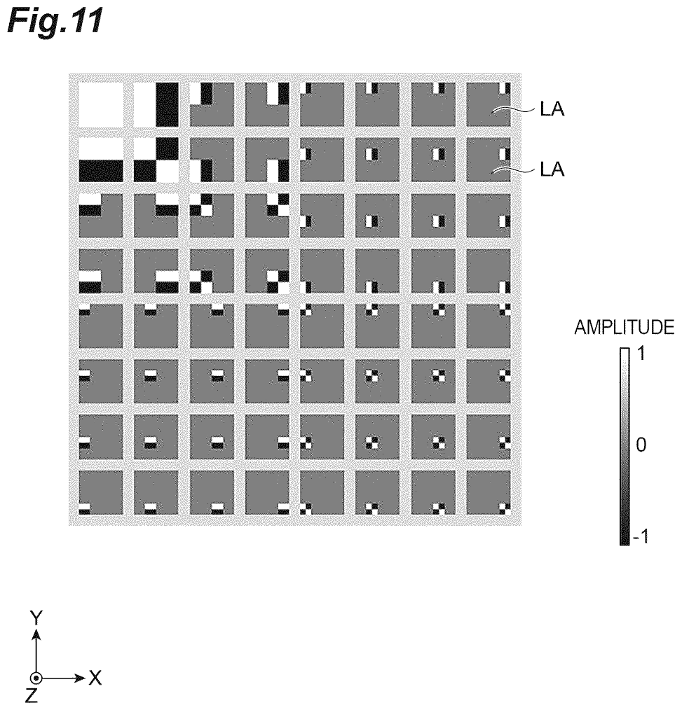

FIG. 11 is a diagram conceptually showing another example of the plurality of optical images output from the plurality of phase modulation regions 151. This example shows the plurality of optical images LA used as base images for discrete wavelet transform (DWT). As in this example, by performing the discrete wavelet transform on the light intensity distribution of the final optical image and outputting the obtained plurality of base images respectively from the plurality of phase modulation regions 151, the final optical image can also be formed. In addition, by changing the magnitude of the drive current of the plurality of electrodes 161 respectively corresponding to the plurality of phase modulation regions 151, a degree of contribution of each base image to the final optical image can be individually adjusted to present a dynamic optical image that changes over time.

Also, the method is not limited to the discrete cosine transform and the discrete wavelet transform, and for example, from a collection of plurality of optical images to be displayed in the far field, their base images may be learned by machine learning (such as principal component analysis or dictionary learning). In addition, in the example shown in FIG. 10, the periods in the two mutually orthogonal directions (X and Y directions) vary for each phase modulation region 151, but the period in only one direction (X or Y direction) may vary for each phase modulation region 151.

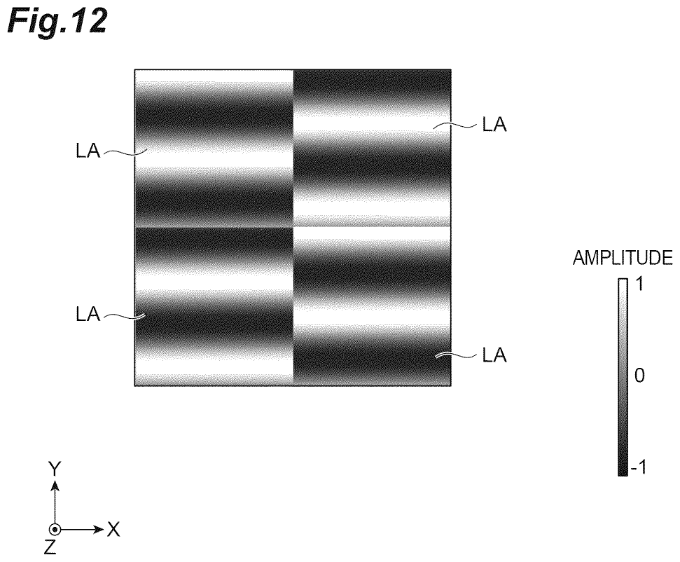

FIG. 12 is a diagram conceptually showing yet another example of the plurality of optical images output from the plurality of phase modulation regions 151. FIG. 12 shows a total of four optical images LA arranged in two columns in the X direction and two rows in the Y direction. These are optical images respectively output from a total of four phase modulation regions 151 arranged in two columns in the X direction and two rows in the Y direction. In this example, the light intensity distribution of the optical images LA output from each of the phase modulation regions 151 includes a sinusoidal distribution that changes periodically along the Y direction. In addition, the phase in the Y direction of the sinusoidal light intensity distribution of the optical images LA output from each of the two phase modulation regions 151 located on one diagonal is different from the phase in the Y direction of the sinusoidal light intensity distribution of the optical images LA output from each of the two phase modulation regions 151 located on the other diagonal. In this example, by changing a ratio of the magnitude of the drive current of the two electrodes 161 corresponding to the two phase modulation regions 151 located on one diagonal to the magnitude of the drive current of the two electrodes 161 corresponding to the two phase modulation regions 151 located on the other diagonal, the phase of the sinusoidal light intensity distribution presented in the final optical image can be freely changed. As in the example shown in FIG. 12, the phases in only one direction (Y direction) of the sinusoidal light intensity distribution of the optical image LA output from each of at least two phase modulation regions 151 may differ from each other. Also, the light intensity distribution of the optical image LA output from each of the at least two phase modulation regions 151 may include a sinusoidal distribution that changes periodically along two directions (X and Y directions). In that case, the phases in each direction of the sinusoidal light intensity distribution of the at least two optical images LA respectively output from the at least two phase modulation regions 151 may differ from each other between the optical images LA.

Next, a phase distribution design method that takes into consideration the phase synchronization of the optical images output from each of the plurality of phase modulation regions 151 will be described in detail. Also, in the following description, the plurality of different refractive index regions 15b may be referred to as a “plurality of points.” That is, the method described below is a method for designing the phase distribution φ(x, y) of two or more phase modulation regions 151 that individually modulate the phase of light at the plurality of points distributed two-dimensionally. In addition, in the following description, the term “real space” indicates a space of the phase modulation regions 151, and the term “wave number space” indicates a space of optical images (also called a beam pattern) in the irradiation region.

### [First Design Method]

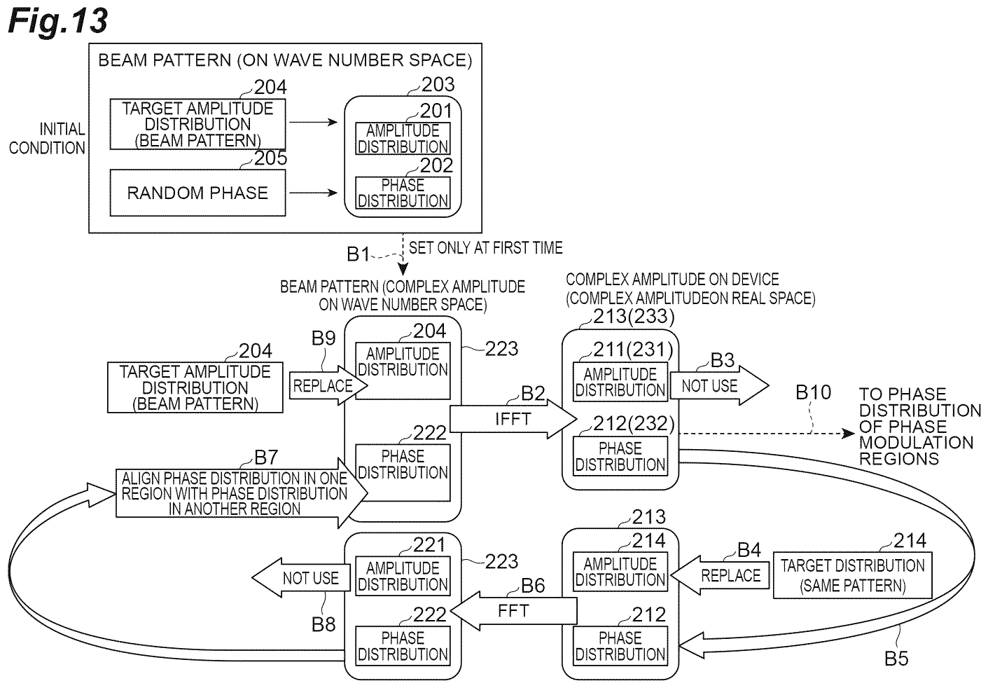

FIG. 13 is a diagram conceptually showing a first design method. First, as a first step, initial conditions are set (arrow B1 in the figure). For each phase modulation region 151, a first function 203, which is a complex amplitude distribution function that includes an initial value 201 for the amplitude distribution in the wave number space and an initial value 202 for the phase distribution in the wave number space, is set. When the initial value 201 of the amplitude distribution in the wave number space is defined as F₀(kx, ky) and the initial value 202 of the phase distribution in the wave number space is defined as θ0(kx, ky), the first function 203 is expressed as F₀(kx, ky)·e^{iθ0 (kx, ky)}. In this case, the initial value 201 of the amplitude distribution in the wave number space may be a target amplitude distribution 204 predetermined in the wave number space. Also, when the target amplitude distribution 204 in the wave number space is defined as F₀(kx, ky), the light intensity distribution (that is, a desired optical image) is given as F₀²(kx, ky). In addition, the initial value 202 of the phase distribution in the wave number space may be a random phase distribution 205.

Further, in the first step, for each phase modulation region 151, the first function 203 is transformed, for example, by inverse Fourier transform such as Inverse fast Fourier transform (IFFT) into a second function 213, which is a complex amplitude distribution function including an amplitude distribution 211 of the real space and a phase distribution 212 in the real space (arrow B₂ in the figure). When the amplitude distribution 211 of the real space is defined as A(x, y) and the phase distribution 212 of the real space is φ(x, y), the second function 213 is expressed as A(x, y)·e^{iφ(kx, ky)}.

Next, as a second step, the amplitude distribution 211 of the second function 213 in each phase modulation region 151 is replaced with a target amplitude distribution 214 based on a predetermined target intensity distribution in the real space (arrows B3 and B4 in the figure). For example, when a predetermined target intensity distribution is defined as A₀²(x, y), the target amplitude distribution is given as A₀(x, y). In one example, the predetermined target intensity distribution A₀²(x, y) is constant regardless of x and y, and the target amplitude distribution A₀(x, y) is also constant regardless of x and y. Also, in this case, the phase distribution 212 of the second function 213 in each phase modulation region 151 is maintained as it is (arrow B5 in the figure). Then, for each phase modulation region 151, the second function 213 after the replacement is transformed by Fourier transform such as fast Fourier transform (FFT) into a third function 223, which is a complex amplitude distribution function including an amplitude distribution 221 in the wave number space and a phase distribution 222 in the wave number space (arrow B6 in the figure). When the amplitude distribution 221 in the wave number space is F(kx, ky) and the phase distribution 222 in the wave number space is θ(kx, ky), the third function 223 is expressed as F(kx, ky)·e^{iθ(kx, ky)}.

Next, as a third step, the phase distribution 222 of the third function 223 in each phase modulation region 151 is aligned with the phase distribution 222 of the third function 223 in one of the plurality of phase modulation regions 151 (arrow B7 in the figure). In this case, the one phase modulation region 151 that serves as a reference for aligning the phase distribution 222 is arbitrarily determined. Also, in this third step, the amplitude distribution 221 of the third function 223 in each phase modulation region 151 is replaced with the target amplitude distribution 204 (arrows B8 and B9 in the figure). Then, for each phase modulation region 151, the third function 223 after the replacement is transformed by inverse Fourier transform such as IFFT into a fourth function 233, which is a complex amplitude distribution function including an amplitude distribution 231 in the real space and a phase distribution 232 in the real space (arrow B2 in the figure). When the amplitude distribution 231 in the real space is A(x, y) and the phase distribution 232 in the real space is defined as φ(x, y), the fourth function 233 is expressed as A(x, y)·e^{iφ(kx, ky)}. Alternatively, for the phase distribution in the wave number space of the phase modulation region 151, an average value of the phases of all the phase modulation regions 151 may be calculated for each point in the wave number space, and the same value may be assigned to the corresponding points of all the phase modulation regions.

Thereafter, the second and third steps are repeated while the second function 213 in the second step is replaced with the fourth function 233. Also, each time the third step is repeated, a position of the one phase modulation region 151 serving as the reference for aligning the phase distribution 222 may be fixed without being changed. Then, the phase distribution 232 of the fourth function 233 transformed by the final third step is set as the phase distribution φ(x, y) of each phase modulation region 151 (arrow B10 in the figure).

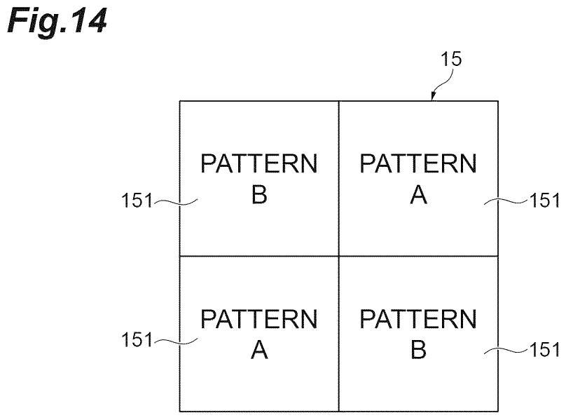

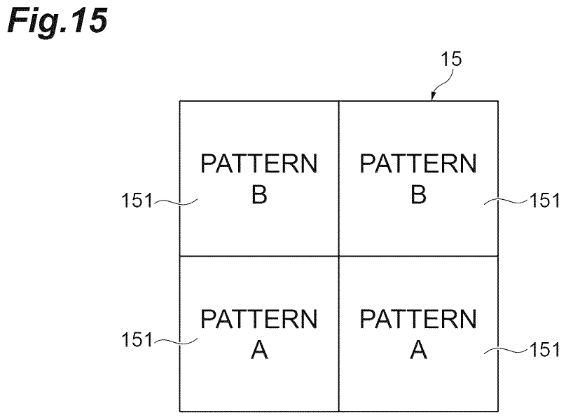

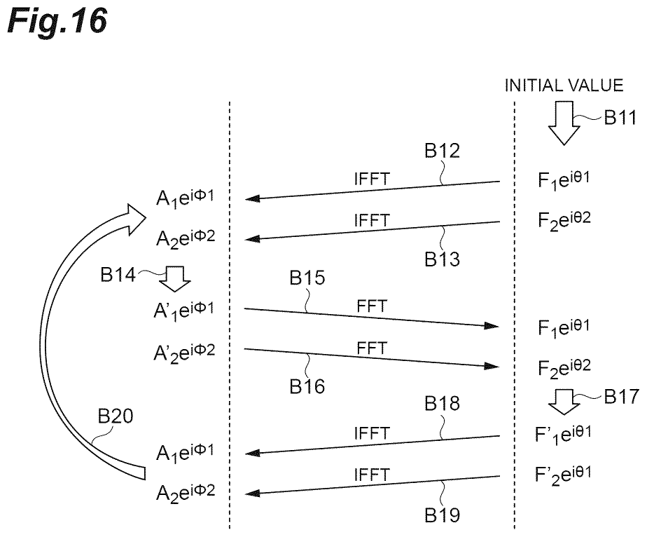

As an example, as shown in FIG. 14, a phase modulation layer 15 having a total of four phase modulation regions 151 arranged in two columns in the X direction and two rows in the Y direction is considered. Among others, it is assumed that two phase modulation regions 151 located on a diagonal have a phase distribution pattern A, and two phase modulation regions 151 located on the opposite diagonal have a phase distribution pattern B. Alternatively, as shown in FIG. 15, two phase modulation regions 151 in the first row may have the phase distribution pattern B and two phase modulation regions 151 in the second row may have the phase distribution pattern A. FIG. 16 is a diagram conceptually showing a method for designing the phase distribution patterns A and B.

As the first step, initial values are set (arrow B11 in the figure). That is, for the phase distribution pattern A, a first function F₁(kx, ky)·e^{iθ1}(kx, ky) is set, which is a complex amplitude distribution function including an initial value of an amplitude distribution F₁(kx, ky) in the wave number space and an initial value of a phase distribution θ1(kx, ky) in the wave number space (hereinafter abbreviated as F₁e^{iθ1}). Also, for the phase distribution pattern B, a first function F₂(kx, ky)·e^{iθ2}(kx, ky) is set, which is a complex amplitude distribution function including an initial value of an amplitude distribution F₂(kx, ky) in the wave number space and an initial value of a phase distribution θ2(kx, ky) in the wave number space (hereinafter abbreviated as F₂e^{iθ2}). Then, the first function F₁·e^{iθ1} of the phase distribution pattern A is transformed by inverse Fourier transform such as IFFT into a second function A₁(x, y)·e^{iφ1(x, y)}, which is a complex amplitude distribution function including an amplitude distribution A₁(x, y) of the real space and a phase distribution φ1(x, y) in the real space (arrow B12 in the figure. Hereinafter abbreviated as A₁·e^{iφ1}). Similarly, the first function F₂(x, y)·e^{iθ2(x, y)} of the phase distribution pattern B is transformed by inverse Fourier transform such as IFFT into a second function A₂(x, y)·e^{iφ2(x, y)}, which is a complex amplitude distribution function including an amplitude distribution A₂(x, y) of the real space and a phase distribution φ2(x, y) in the real space (arrow B13 in the figure. Hereinafter, abbreviated as A₂·e^{iφ2}).

Next, as the second step, the amplitude distribution A₁ of the second function A₁·e^{iφ1} is replaced with a target amplitude distribution A₁′ based on a predetermined target intensity distribution in the real space. Similarly, the amplitude distribution A₂ of the second function A₂·e^{iφ2} is replaced with a target amplitude distribution A₂ based on a predetermined target intensity distribution in the real space (arrow B14 in the figure). In this case, the phase distributions φ1 and φ2 remain unchanged. Then, the second function A₁′·e^{iφ1} after the replacement is transformed, for example, by Fourier transform such as FFT into a third function F₁·e^{iθ1}, which is a complex amplitude distribution function including the amplitude distribution F₁ of the wave number space and the phase distribution θ1 of the wave number space (arrow B15 in the figure). Similarly, the second function A₂′·e^{iφ2} after the replacement is transformed, for example, by Fourier transform such as FFT into a third function F₂·e^{iθ2}, which is a complex amplitude distribution function including the amplitude distribution F₂ of the wave number space and the phase distribution θ2 of the wave number space (arrow B16 in the figure).

Next, as the third step, the phase distribution θ2 of the third function F₂·e^{iθ2} is aligned with the phase distribution θ1 of the third function F₁·e^{iθ1}. Also, the amplitude distribution F₁ of the third function F₁·e^{iθ1} and the amplitude distribution F₂ of the third function F₂·e^{iθ2} are respectively replaced with target amplitude distributions F₁′ and F₂′ (arrow B17 in the figure). Then, the third function F₁′·e^{iθ1} is transformed by inverse Fourier transform such as IFFT into a fourth function A₁·e^{iφ1}, which is a complex amplitude distribution function including the amplitude distribution A₁ of the real space and the phase distribution φ1 in the real space (arrow B18 in the figure). Similarly, the third function F₂′·e^{iθ1} is transformed by inverse Fourier transform such as IFFT into a fourth function A₂·e^{iφ2}, which is a complex amplitude distribution function including the amplitude distribution A₂ of the real space and the phase distribution φ2 in the real space (arrow B19 in the figure).

Thereafter, the second step and the third step are repeated while the second functions A₁·e^{iφ1} and A₂·e^{iφ2} in the second step are replaced respectively with the fourth functions A₁·e^{iφ1} and A₂·e^{iφ2} (arrow B20 in the figure). Then, the phase distribution φ1 of the fourth function A₁·e^{iφ1} transformed by the final third step is set as the phase distribution T(x, y) of the phase distribution pattern A. Also, the phase distribution φ2 of the fourth function A₂·e^{iφ2} transformed by the final third step is set as the phase distribution φ(x, y) of the phase distribution pattern B.

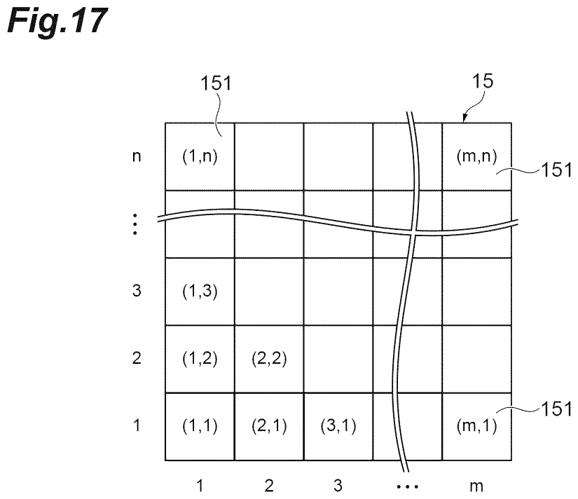

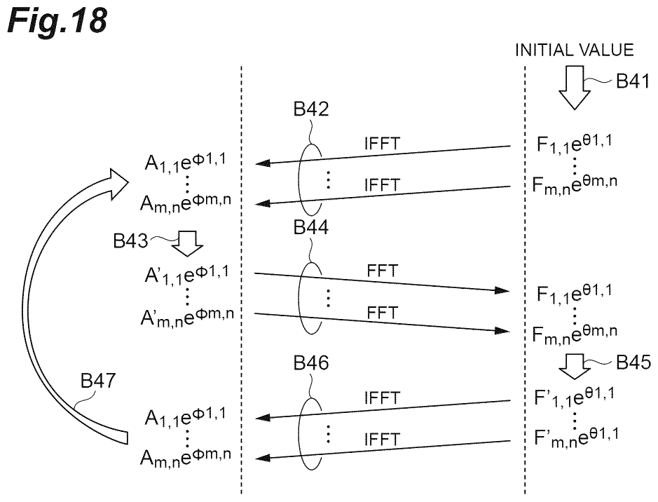

Also, as another example, the phase modulation layer 15 shown in FIG. 17, which has a total of m×n phase modulation regions 151 with m columns in the X direction and n rows in the Y direction, is considered. The m×n phase modulation regions 151 have mutually different phase distribution patterns. FIG. 18 is a diagram conceptually showing a method for designing m×n phase distribution patterns.

As the first step, initial values are set (arrow B41 in the figure). That is, for m×n phase modulation regions 151, first functions F_{1,1}(kx, ky)·e^{iθ1,1(kx, ky)} to F_{m,n}(kx, ky)·e^{iθm,n(kx, ky)} are set, which are complex amplitude distribution functions including initial values of amplitude distributions F_{1,1}(kx, ky) to F_{m,n}(kx, ky) in the wave number space and initial values of phase distributions θ1,1(kx, ky) to θm,n(kx, ky) in the wave number space, respectively (hereinafter abbreviated as F_{1,1}e^{iθ1,1} to F_{m,n}e^{iθm,n}). Then, for each phase modulation region 151, the first functions F_{1,1}e^{i∝1,1} to F_{m,n}e^{iθm,n} are transformed by inverse Fourier transform such as IFFT into second functions A_{1,1}(x, y)·e^{iφ1,1(x, y)} to A_{m,n}(x, y)·e^{iφm,n(x, y)}, which are complex amplitude distribution functions including amplitude distributions A_{1,1}(x, y) to A_{m,n}(x, y) of the real space and phase distributions φ1,1(x, y) to φm,n(x, y) in the real space (arrow group B42 in the figure. Hereinafter, abbreviated as A_{1,1}e^{iφ1,1} to A_{m,n}e^{iφm,n}).

Next, as the second step, for each phase modulation region 151, the amplitude distributions A_{1,1} to Am,n of the second functions A_{1,1}e^{iφ1,1} to A_{m,n}e^{iφm,n} are replaced with target amplitude distributions A′_{1,1} to A′_{m,n} based on predetermined target intensity distribution in the real space (arrow B43 in the figure). In this case, the phase distributions φ1,1 to φm,n remain unchanged. Then, for each phase modulation region 151, the second functions A′_{1,1}e^{iφ1,1} to A′_{m,n}e^{iφm,n} after the replacement are transformed, for example, by Fourier transform such as FFT into third functions F_{1,1}e^{iθ1,1} to F_{m,n}e^{iθm,n}, which are complex amplitude distribution functions including the amplitude distributions F_{1,1} to F_{m,n} of the wave number space and the phase distributions θ1,1 to θm,n of the wave number space, respectively (arrow group B44 in the figure).

Next, as the third step, all the phase distributions θ1,1 to θm,n of the third functions F_{1,1}^{eiθ1,1} to F_{m,n}e^{iθm,n} are aligned to the phase distribution θ1,1 of the third function F_{1,1}^{eiθ1,1}. Also, the amplitude distributions F_{1,1} to F_{m,n} of the third functions F_{1,1}^{eiθ1,1} to F_{m,n}e^{iθm,n} are replaced with the target amplitude distributions F′_{1,1} to F′_{m,n}, respectively (arrow B45 in the figure). Then, the third functions F′_{1,1}^{eiθ1,1} to F′_{m,n}e^{iθm,n} are transformed by inverse Fourier transform such as IFFT into fourth functions A_{1,1}e^{iφ1,1} to A_{m,n}e^{iφm,n}, which are complex amplitude distribution functions including the amplitude distributions A_{1,1} to Am,n of the real space and the phase distributions φ1,1 to φm,n in the real space (arrow group B46 in the figure).

Thereafter, the second step and the third step are repeated while the second functions A_{1,1}e^{iφ1,1} to A_{m,n}e^{iφm,n} from the second step are replaced respectively with the fourth functions A_{1,1}e^{iφ1,1} to A_{m,n}e^{iφm,n}, (arrow B47 in the figure). Then, the phase distributions φ1,1 to φm,n of the fourth functions A_{1,1}e^{iφ1,1} to A_{m,n}e^{iφm,n} transformed by the final third step are set as the phase distributions φ(x, y) of the respective phase modulation regions 151.

### Second Design Method

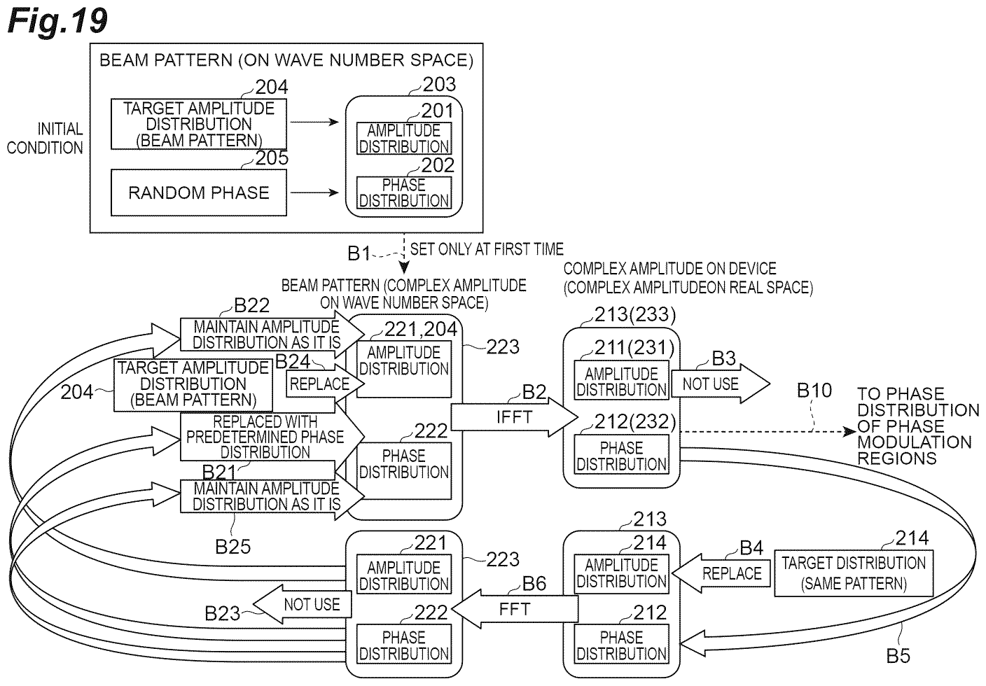

FIG. 19 is a diagram conceptually showing a second design method. Also, since the first and second steps are the same as those of the first design method described above, their description is omitted.

In the first third step, the phase distribution 222 of the third function 223 in each phase modulation region 151 is replaced with a predetermined phase distribution that is the same among the plurality of phase modulation regions 151 (the first process, arrow B21 in the figure). Phase values of the plurality of points (kx, ky) in a predetermined phase distribution may be equal to each other. In this case, the phase values of the plurality of points (kx, ky) in the predetermined phase distribution may be zero (0 rad). In this case, the amplitude distribution 221 is maintained as it is (arrow B22 in the figure). Then, the third function 223 is transformed into the fourth function 233 by inverse Fourier transform such as IFFT (arrow B2 in the figure).

The second function 213 is replaced with the fourth function 233 and the second step is performed again, and in the subsequent (second) third step, the amplitude distribution 221 of the third function 223 is replaced with the target amplitude distribution 204 (the second process, arrows B23 and B24 in the figure). In this case, the phase distribution 222 is maintained as it is (arrow B25 in the figure). Then, the third function 223 after the replacement is transformed to the fourth function 233 by inverse Fourier transform such as IFFT (arrow B2 in the figure).

Thereafter, the second step and the third step are repeated while the second function 213 in the second step is replaced with the fourth function 233. In that case, in the repetition of the third step, the replacement of the phase distribution 222 with the predetermined phase distribution (the first process) and the replacement of the amplitude distribution 221 with the target amplitude distribution 204 (the second process) are alternately performed. The predetermined phase distribution may be fixed without being changed in a plurality of the first processes by repeating the third step. The phase distribution 232 of the fourth function 233 transformed by the final third step is set as the phase distribution φ(x, y) of each phase modulation region 151 (arrow B10 in the figure).

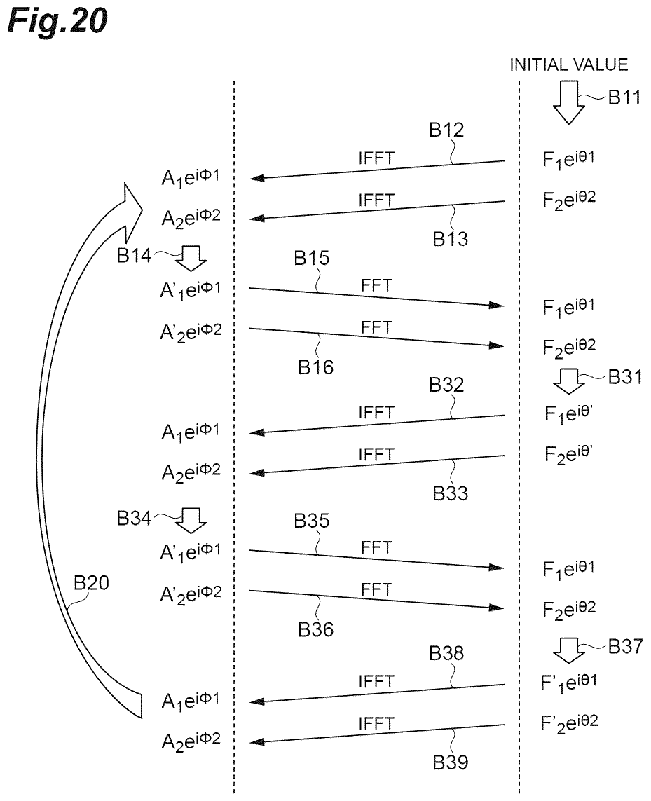

As an example, the phase modulation layer 15 shown in FIG. 14 or 15, which has a total of four phase modulation regions 151 arranged in two columns in the X direction and two rows in the Y direction, is considered. Of these, two phase modulation regions 151 have the phase distribution pattern A, and the other two phase modulation regions 151 have the phase distribution pattern B. FIG. 20 is a diagram conceptually showing a method for designing the phase distribution patterns A and B. Also, since the first and second steps are the same as those in the first design method described above, their description is omitted.

In the first third step, the phase distribution θ1 of the third function F₁·^{eiθ1} and the phase distribution θ2 of the third function F₂·e^{iθ2} are replaced with a predetermined phase distribution θ′ common to the phase distribution patterns A and B (arrow B31 in the figure). In this case, the amplitude distribution F₁ and the amplitude distribution F₂ remain unchanged. Then, the third function F₁·e^{iθ′} and the third function F₂·e^{iθ′} are transformed by inverse Fourier transform such as IFFT into the fourth function A₁·e^{iφ1} and the fourth function A₂·e^{iφ2}, respectively, (arrows B32 and B33 in the figure).

The second function A₁·e^{iφ1} and the second function A₂·e^{iφ2} are replaced with the fourth function A₁·e^{iφ1} and the fourth function A₂·e^{iφ2}, respectively, and the second step is performed again (arrows B34 to B36 in the figure), and in the subsequent (second) third step, the amplitude distribution F₁ of the third function F₁·e^{iθ1} and the amplitude distribution F₂ of the third function F₂·e^{iθ2} are replaced with the target amplitude distributions F₁′ and F₂′, respectively (arrow B37 in the figure). Then, the third function F₁′·e^{iθ1} and the third function F₂′·e^{iθ2} are transformed by inverse Fourier transform such as IFFT into the fourth function A₁·e^{iφ1} and the fourth function A₂·e^{iφ2}, respectively, (arrows B38 and B39 in the figure).

Thereafter, the second and third steps are repeated while the second function A₁·e^{iφ1} and the second function A₂·e^{iφ2} in the second step are replaced with the fourth function A₁·e^{iφ1} and the fourth function A₂·e^{iφ2}, respectively (arrow B20 in the figure). In that case, in the repetition of the third step, the replacement of the phase distributions θ1 and θ2 (the first process, arrow B31 in the figure) and the replacement of the amplitude distributions F₁ and F₂ (the second process, arrow B37 in the figure) are alternately performed. Then, the phase distribution φ1 of the fourth function A₁·e^{iφ1} transformed by the final third step is set as the phase distribution φ(x, y) of the phase distribution pattern A. Also, the phase distribution φ2 of the fourth function A₂·e^{iφ2} transformed by the final third step is set as the phase distribution φ(x, y) of the phase distribution pattern B.

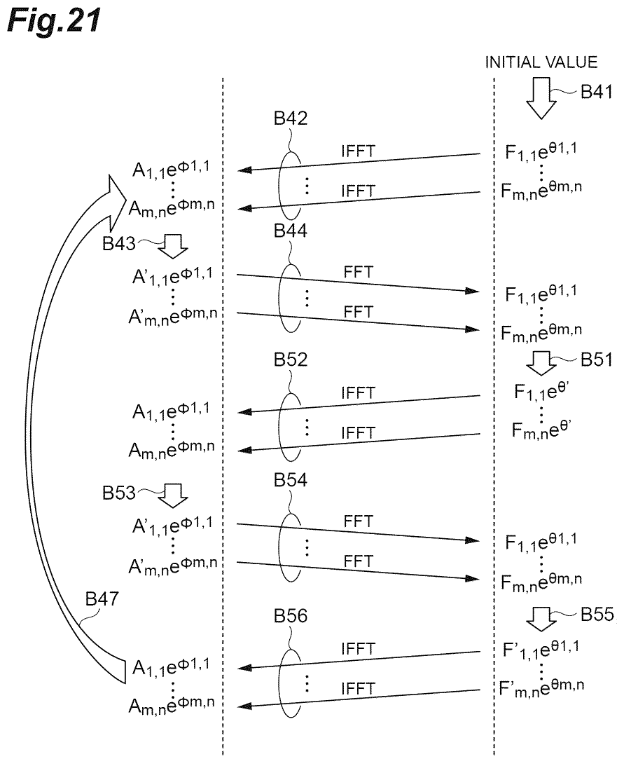

Also, as another example, the phase modulation layer 15 shown in FIG. 17, which has a total of m×n phase modulation regions 151 with m columns in the X direction and n rows in the Y direction, is considered. The m×n phase modulation regions 151 have mutually different phase distribution patterns. FIG. 21 is a diagram conceptually showing a method for designing m×n phase distribution patterns. In addition, since the first and second steps are similar to the first design method described above, a description thereof is omitted.

In the first third step, all the phase distributions θ1,1 to θm,n of the third functions F_{1,1}^{eiθ1,1} to F_{m,n}e^{iθm,n} are replaced with the common and predetermined phase distribution θ′ (the first process, arrow B51 in the figure). In this case, the amplitude distributions F_{1,1} to F_{m,n} remain unchanged. Then, the third functions F_{1,1}e^{iθ′} to F_{m,n}e^{iθ′} are transformed by inverse Fourier transform such as IFFT into the fourth functions A_{1,1}e^{iφ1,1} to A_{m,n}e^{iφm,n}, respectively (arrow group B52 in the figure).

The second functions A_{1,1}e^{iφ1,1} to A_{m,n}e^{iφm,n} are replaced with the fourth functions A_{1,1}e^{iφ1,1} to A_{m,n}e^{iφm,n} and the second step is performed again (arrow B53 and arrow group B54 in the figure), and in the subsequent (second) third step, the amplitude distributions F_{1,1} to F_{m,n} of the third functions F_{1,1}^{eiθ1,1} to F_{m,n}e^{iθm,n} are replaced with the target amplitude distributions F′1,1 to F′m,n (the second process, arrow B55 in the figure). Then, the third functions F′_{1,1}^{eiθ1,1} to F′_{m,n}e^{iθm,n} are transformed by inverse Fourier transform such as IFFT into the fourth functions A_{1,1}e^{iφ1,1} to A_{m,n}e^{iφm,n}, respectively (arrow group B56 in the figure).

Thereafter, the second and third steps are repeated while the second functions A_{1,1}e^{iφ1,1} to A_{m,n}e^{iφm,n} in the second step are replaced with the fourth functions A_{1,1}e^{iφ1,1} to A_{m,n}e^{iφm,n}, respectively (arrow B47 in the figure). In that case, in the repetition of the third step, the replacement of the phase distributions θ1,1 to θm,n (the first process, arrow B51 in the figure) and the replacement of the amplitude distributions F_{1,1} to F_{m,n} (the second process, arrow B55 in the figure) are alternately performed. Then, the respective phase distributions θ1,1 to θm,n of the fourth functions A_{1,1}e^{iφ1,1} to A_{m,n}e^{iφm,n} transformed by the final third step are set as the phase distribution φ(x, y) of each phase modulation region 151.

Effects obtained by the semiconductor light emitting element 1A of the present embodiment described above will be described. In the semiconductor light emitting element 1A, one or both of the electrode portion 16 and the electrode portion 17 include a plurality of electrodes (for example, the plurality of electrodes 161) that respectively overlap the plurality of phase modulation regions 151. The plurality of electrodes are electrically isolated from each other. Accordingly, it is possible to supply an independent current to each of the plurality of electrodes. Thus, the light emission intensity of each of a plurality of regions of the active layer 12 that supply light to each of the plurality of phase modulation regions 151 is controlled independently, and the light intensity of each of the plurality of optical images LA output from each of the plurality of phase modulation regions 151 is also controlled independently. The plurality of optical images LA are projected onto the common irradiation region. In this case, since the optical images LA output from each of the plurality of phase modulation regions 151 are phase-locked to each other, the plurality of optical images LA can interfere with each other in the common irradiation region. In this way, according to the semiconductor light emitting element 1A of the present embodiment, the light intensities of the plurality of optical images LA output from the plurality of phase modulation regions 151 can be individually adjusted while causing the plurality of optical images LA to interfere with each other to form a single final optical image. Thus, the final optical image can be dynamically changed

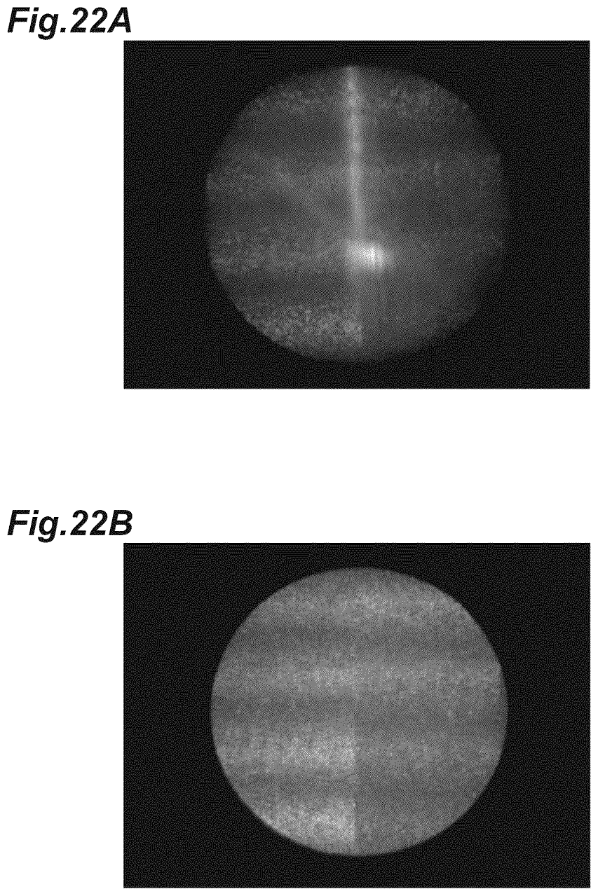

Also, as described above, when the present inventors prototyped a semiconductor light emitting element described in the patent document, spot-like stray light unrelated to the intended optical image was output from the semiconductor light emitting element along with the intended optical image. FIG. 22A is an image showing a far-field pattern including spot-like stray light observed in the prototyped semiconductor light emitting element. The present inventors have tried and tested a structure that can reduce stray light, and when the emission wavelength of the active layer 12 was set to 940 nm, by providing an InGaAs layer of a certain thickness (for example, 500 nm) between the electrode portion 16 located on a side opposite to the light-exit surface and the contact layer 14 made of GaAs, the stray light was significantly reduced. FIG. 22B is an image showing a far-field pattern observed in a semiconductor light emitting element provided with an InGaAs layer.

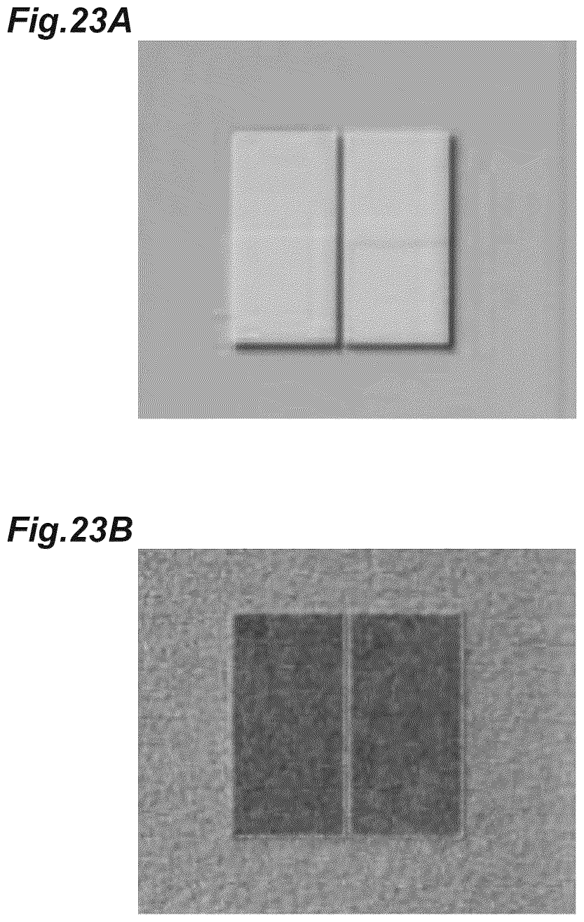

InGaAs has a relatively high light absorption property at a wavelength of 940 nm. In addition, since InGaAs is lattice-mismatched to GaAs, a surface of the InGaAs layer becomes a rough surface. From these facts, it is conceivable that the light emitted from the phase modulation layer 15 toward a side opposite to the light-exit surface is absorbed and scattered before it reaches the electrode portion 16, thereby reducing reflection of the light at the electrode portion 16, which led to reduction in the stray light. In other words, the reflection of the light on the electrode portion 16 is considered to be the cause of the stray light. FIGS. 23A and 23B are images each showing the result of observing the vicinity of the contact layer 14 of the semiconductor light emitting element using a Nomarski microscope. FIG. 23A shows a case in which an InGaAs layer is not provided, and FIG. 23B shows a case in which an InGaAs layer is provided. Referring to FIG. 23A, no light scattering occurs when the InGaAs layer is not provided. In contrast, referring to FIG. 23B, light scattering occurs when the InGaAs layer is provided.

Also, in a semiconductor light emitting element in which the phase modulation layer 15 is not divided into a plurality of phase modulation regions 151, no stray light was observed. Accordingly, it is inferred that stray light is caused when light having a certain phase distribution emitted from a certain phase modulation region 151 and reflected by the electrode portion 16 mixes with light having another phase distribution output from an adjacent phase modulation region 151 to cause a disturbance in its wavefront.

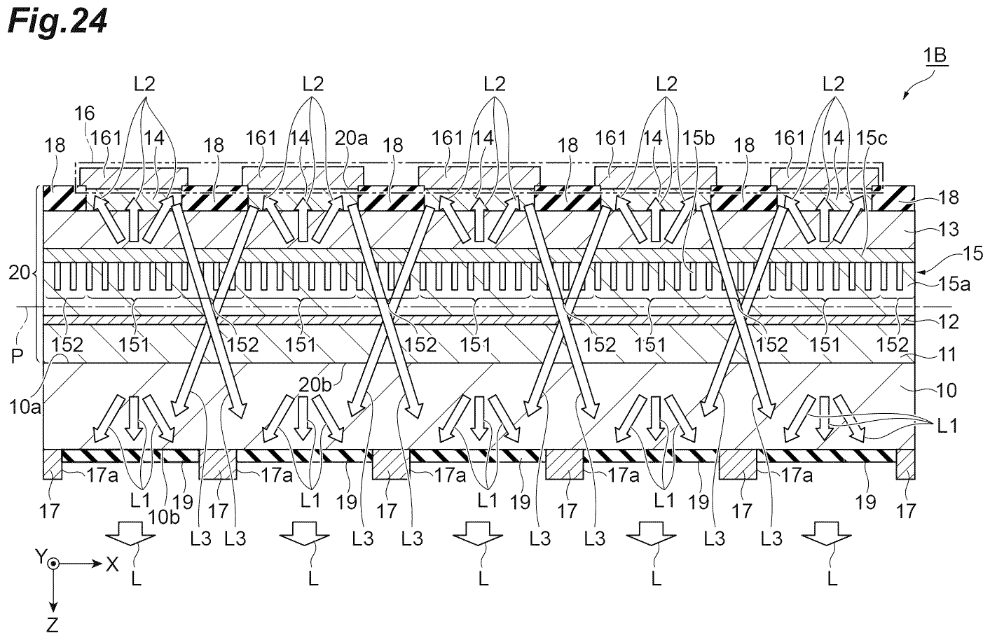

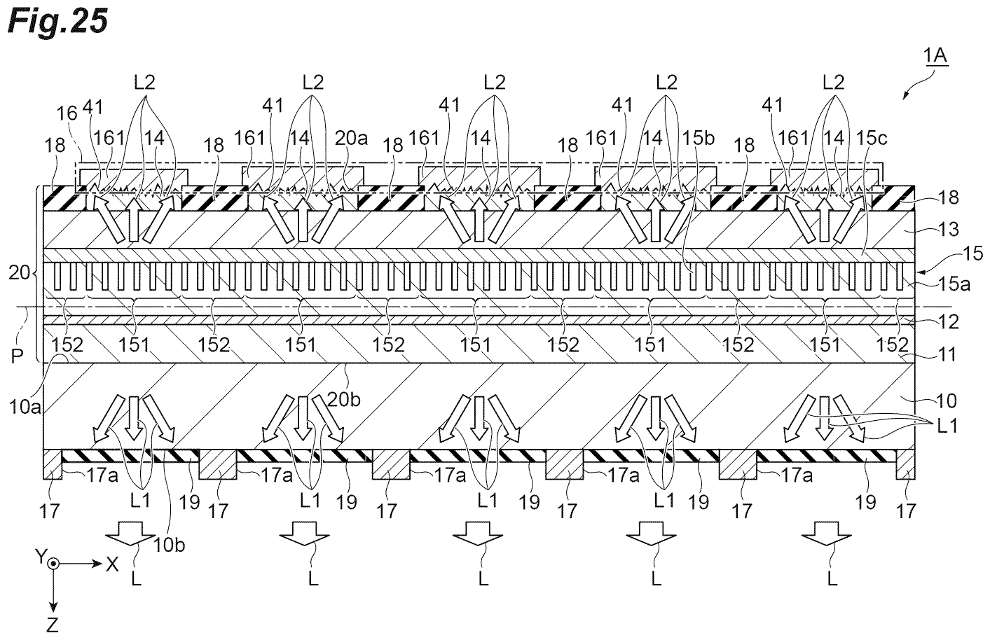

In the semiconductor light emitting element 1A of the present embodiment, the electrode portion 16 is formed of metal and the reflection reduction structure 41 is configured to reduce reflection of the light emitted from each phase modulation region 151 on the electrode portion 16. FIG. 24 is a cross-sectional view showing a configuration of a semiconductor light emitting element 1B that does not include the reflection reduction structure 41 and is disclosed in the patent document. As shown in FIG. 24, light L1, which is a part of the laser light output from each phase modulation region 151, is output as the laser light L from the back surface 10b through the openings 17a to the outside of the semiconductor light emitting element 1B. On the other hand, the remaining light L2 of the laser light output from the phase modulation region 151 is reflected at an interface between the contact layer 14 and the electrode portion 16. Then, light L3, which is a part of the reflected light L2, is mixed into the laser light L output from the adjacent phase modulation region 151. This mixing is thought to be the cause of spot-like stray light that is unrelated to the intended optical image. In the present embodiment, as shown in FIG. 25, the light L2 output from the phase modulation region 151 is scattered by the reflection reduction structure 41. Accordingly, it is possible to reduce the reflection of the light L2 and reduce the crosstalk of the light L3 into the laser light L output from the adjacent phase modulation region 151. Thus, according to the present embodiment, the spot-like stray light can be effectively reduced.

As in the present embodiment, the reflection reduction structure 41 may include a structure that scatters the light L2 from each phase modulation region 151 toward the electrode portion 16. The scattering structure may be provided between the electrode portion 16 and both the active layer 12 and the phase modulation layer 15, and may overlap the plurality of phase modulation regions 151 when viewed from the stacking direction. By scattering the light L2 from each phase modulation region 151 toward the electrode portion 16, the reflection at the electrode portion 16 can be reduced. Thus, the stray light can be effectively reduced.

As in the present embodiment, the scattering structure may include an uneven structure formed on the surface of the contact layer 14, that is, the first surface 20a. For example, such a structure can scatter the light L2 traveling from each phase modulation region 151 toward the electrode portion 16.

As in the present embodiment, the uneven structure may be caused by lattice mismatch in the semiconductor stack 20. In this case, the uneven structure can be easily formed.

### First Modification

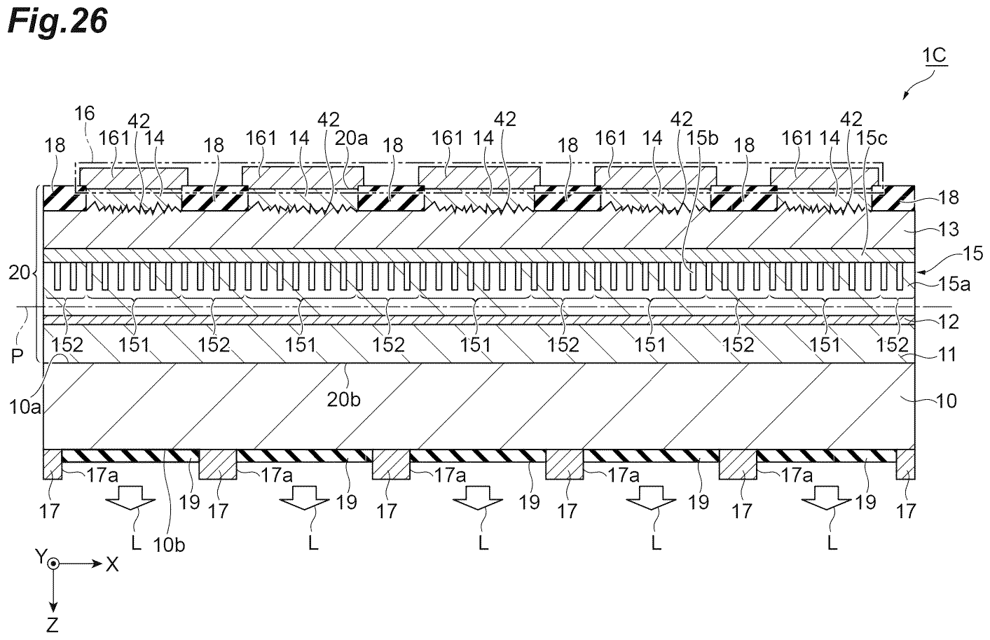

FIG. 26 is a cross-sectional view showing a stacked structure of a semiconductor light emitting element 1C according to a first modification. The semiconductor light emitting element 1C differs from the first embodiment in the position at which the reflection reduction structure is formed. The semiconductor light emitting element 1C has a reflection reduction structure 42 instead of the reflection reduction structure 41 of the first embodiment. Similar to the reflection reduction structure 41, the reflection reduction structure 42 is configured to reduce the reflection of the light emitted from each phase modulation region 151 at the electrode portion 16. The reflection reduction structure 42 includes a structure that scatters the light L2 (see FIG. 25) traveling from each phase modulation region 151 toward the electrode portion 16. The scattering structure is provided between the electrode portion 16 and both the active layer 12 and the phase modulation layer 15, and overlaps the plurality of phase modulation regions 151 when viewed from the stacking direction. The scattering structure includes an uneven structure formed at an interface between two layers adjacent to each other in the semiconductor stack 20. In the illustrated example, the uneven structure is formed at the interface between the cladding layer 13 and the contact layer 14. The details of the uneven structure are the same as those of the uneven structure in the reflection reduction structure 41 of the first embodiment.

As in the present modification, the scattering structure may include an uneven structure formed at the interface between two layers adjacent to each other in the semiconductor stack 20. For example, such a structure can scatter the light L2 traveling from each phase modulation region 151 toward the electrode portion 16.

As in the present modification, the uneven structure may be formed at the interface between the cladding layer 13 and the contact layer 14. In this case, the light L2 traveling from each phase modulation region 151 toward the electrode portion 16 can be effectively scattered.

### Second Modification

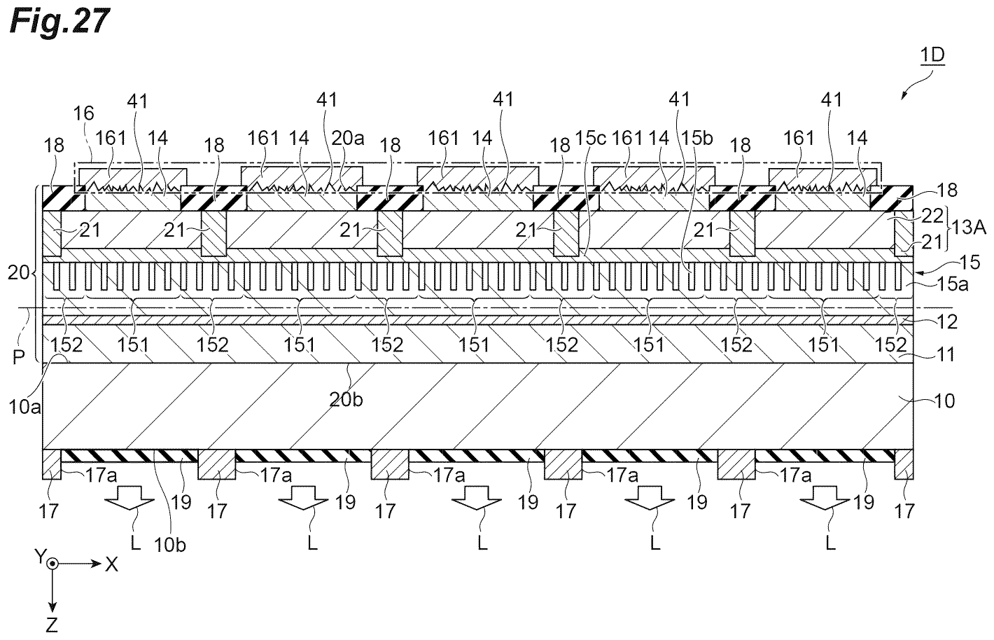

FIG. 27 is a cross-sectional view showing a stacked structure of a semiconductor light emitting element 1D as a second modification of the above-described embodiment. The semiconductor light emitting element 1D differs from the above-described embodiment in that the semiconductor stack 20 has a cladding layer 13A instead of a cladding layer 13. Arrangement of the cladding layer 13A is the same as that of the cladding layer 13 in the above-described embodiment. Since other configurations of the semiconductor light emitting element 1D are the same as those of the above-described embodiment, detailed description thereof is omitted. Also, in the present modification, the electrode portion 16 necessarily includes the plurality of electrodes 161.

The cladding layer 13A includes a high resistance region 21 and a base region 22. The base region 22 has the same configuration as the cladding layer 13 of the above-described embodiment. The high resistance region 21 has a higher resistivity than the base region 22. The high resistance region 21 may be formed of an insulator.

The high resistance region 21 is located between adjacent phase modulation regions 151 when viewed from the stacking direction of the semiconductor stack 20. Also, the high resistance region 21 is provided on the coupling region 152 of the phase modulation layer 15. A region formed by projecting the high resistance region 21 onto the virtual plane P is included in a region formed by projecting the coupling region 152 onto the virtual plane P. When the phase modulation layer 15 is provided between the cladding layer 13A and the active layer 12 as in the illustrated example, the high resistance region 21 extends to the cap region 15c of the phase modulation layer 15 from an interface of the cladding layer 13A closer to the first surface 20a. However, the high resistance region 21 does not contact the base region 15a and the different refractive index region 15b. In other words, in the stacking direction (Z direction) of the semiconductor stack 20, there is a gap between the high resistance region 21 and both the base region 15a and the different refractive index region 15b.

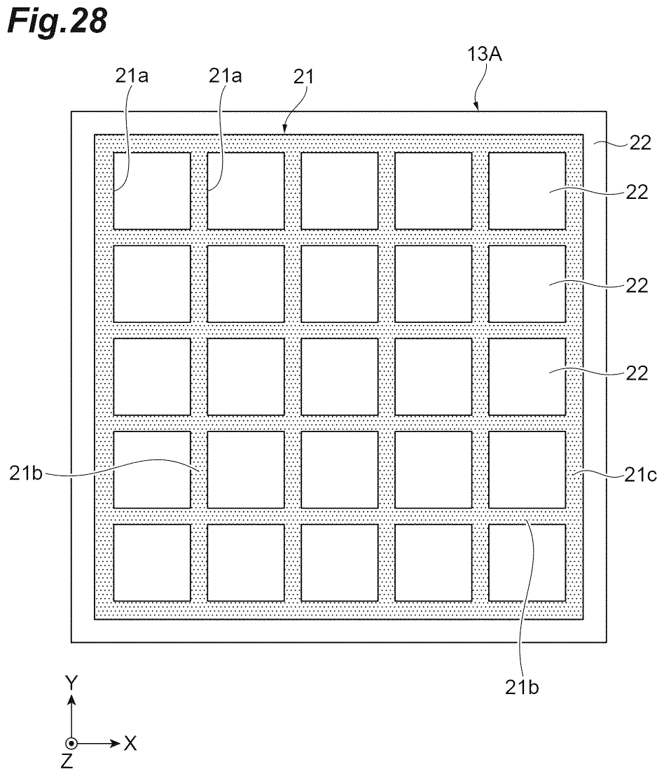

FIG. 28 is a plan view (viewed from the thickness direction) of the cladding layer 13A. As described above, the cladding layer 13A includes the high resistance region 21 and the base region 22. The planar shape of the high resistance region 21 when viewed from the stacking direction of the semiconductor stack 20 is, for example, a lattice shape. The base region 22 is provided inside each of a plurality of openings 21a of the high resistance region 21 formed in a lattice shape.

The planar shape of each of the plurality of openings 21a is, for example, a square or a rectangle. When viewed from the stacking direction of the semiconductor stack 20, each of the plurality of openings 21a overlaps the corresponding phase modulation region 151. When viewed from the stacking direction of the semiconductor stack 20, the high resistance region 21 includes a portion 21b provided between adjacent phase modulation regions 151 and an outer frame-shaped portion 21c collectively surrounding the plurality of phase modulation regions 151.

Also, the high resistance region 21 shown in FIG. 27 penetrates the base region 22 and reaches the phase modulation layer 15, but the high resistance region 21 does not have to reach the phase modulation layer 15. In that case, the lowermost end of the high resistance region 21 is located within the base region 22.

As in the present modification, when viewed from the stacking direction of the semiconductor stack, the cladding layer of the semiconductor stack may include the high resistance region 21 located between adjacent phase modulation regions 151. In this case, it is possible to reduce leakage of an electric current flowing between each electrode 161 and a region of the active layer 12 located directly below the electrode 161 to a region of the active layer 12 located directly below the adjacent electrode 161.

As in the present modification, the high resistance region 21 may reach the phase modulation layer 15 from the interface of the cladding layer 13A on the first surface 20a side. In this case, current leakage can be prevented throughout the entire thickness of the cladding layer 13A.

As in the present modification, the planar shape of the high resistance region 21 when viewed from the stacking direction of the semiconductor stack 20 may be a lattice shape. In this case, the high resistance region 21 can be provided between all of the phase modulation regions 151 when viewed from the stacking direction.

### Third Modification

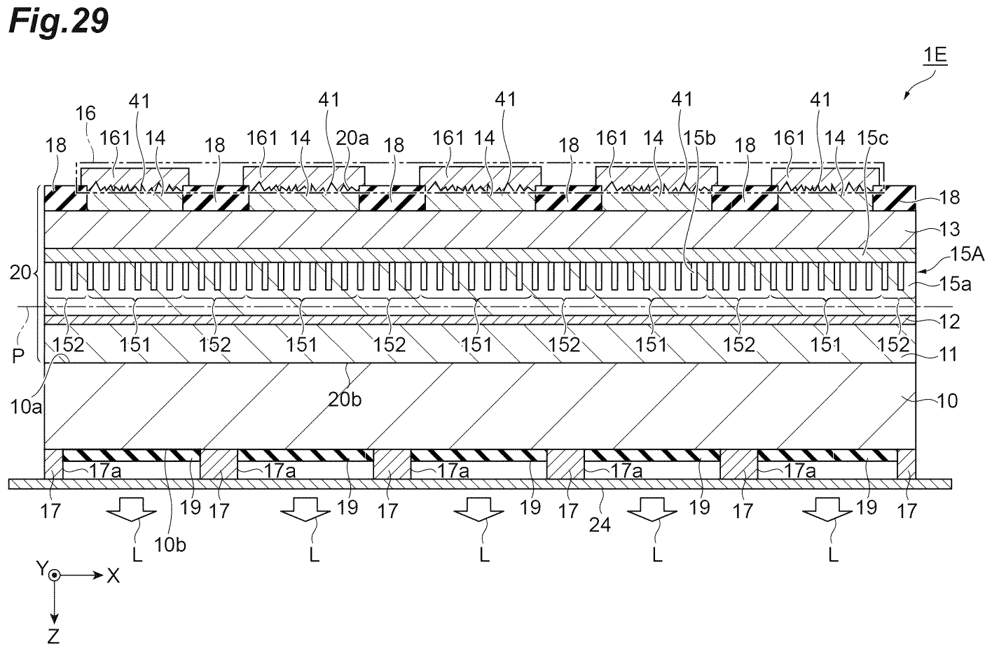

FIG. 29 is a cross-sectional view showing a configuration of a semiconductor light emitting element 1E as a third modification of the above-described embodiment. The semiconductor light emitting element 1E differs from the above-described embodiment in that it includes a phase modulation layer 15A instead of the phase modulation layer 15, and includes a λ/4 plate 24. The λ/4 plate 24 extends along the virtual plane P, and is disposed to face the back surface 10b of the semiconductor substrate 10, that is, the light-exit surface of the semiconductor light emitting element 1E. An axis of the λ/4 plate 24 is orthogonal to the straight line D shown in FIGS. 3 and 4.

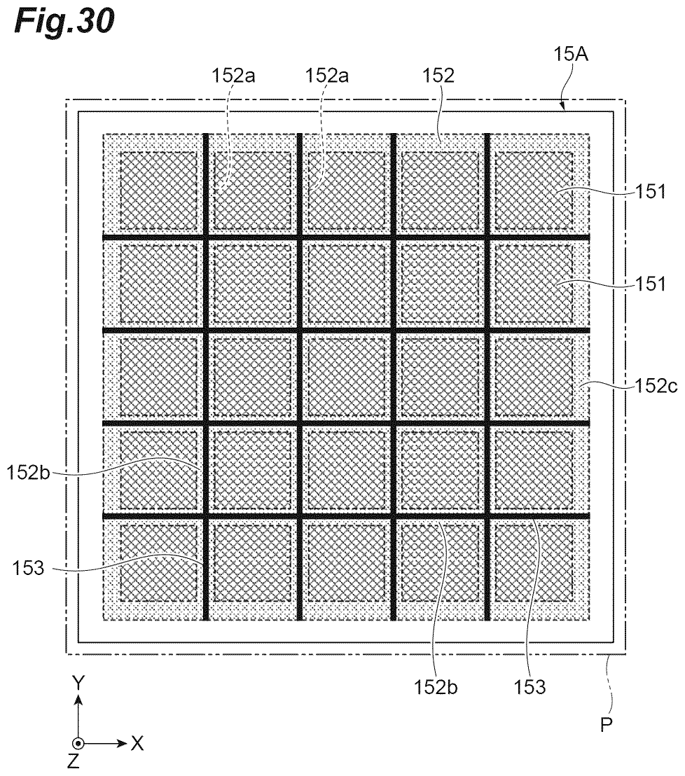

FIG. 30 is a plan view showing the phase modulation layer 15A. The phase modulation layer 15A further has a phase shift region 153 in addition to the configuration of the phase modulation layer 15 of the above-described embodiment. The phase shift region 153 is provided between adjacent phase modulation regions 151. In the illustrated example, the phase shift region 153 is provided inside the portion 152b of the coupling region 152, and is configured by a plurality of portions extending in the X direction and a plurality of portions extending in the Y direction, which intersect each other. The planar shape of the phase shift region 153 when viewed from the stacking direction of the semiconductor stack 20 is, for example, a lattice shape.

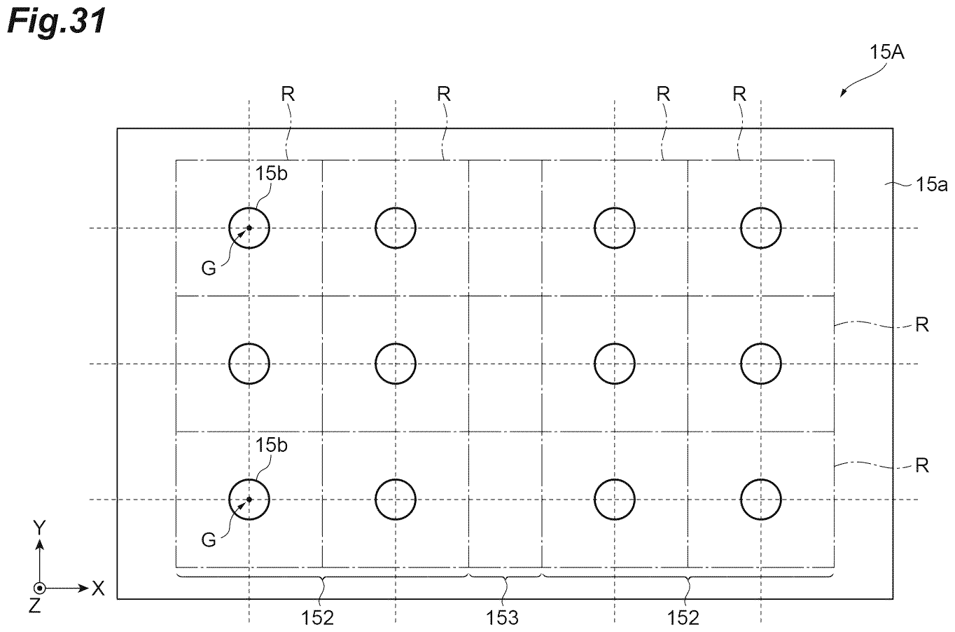

FIG. 31 is a partially enlarged plan view showing the phase shift region 153 and the surrounding coupling region 152. As shown in FIG. 31, the phase shift region 153 is provided between a square lattice set in the coupling region 152 located on one side of the phase shift region 153 and a square lattice set in the coupling region 152 located on the other side. The phase shift region 153 has an arbitrary width. Depending on the width of the phase shift region 153, the square lattice of the coupling region 152 located on one side of the phase shift region 153 and the square lattice of the coupling region 152 located on the other side are displaced from each other. These square lattices are common to the square lattices set in the phase modulation region 151 adjacent to the coupling region 152. Accordingly, the square lattices of the phase modulation regions 151 adjacent to each other are displaced from each other.

In one example, when the lattice constant of the square lattice is a, the phase shift region 153 has a width of n·a+a/2 (n is an integer of 0 or more). Thus, the square lattice of the coupling region 152 located on one side of the phase shift region 153 and the square lattice of the coupling region 152 located on the other side are displaced from each other by n·a+a/2. Accordingly, the square lattices of the phase modulation regions 151 adjacent to each other are displaced from each other by n·a+a/2. In this case, the phases of the optical images LA output from each of the phase modulation regions 151 adjacent to each other are shifted by π (rad) with respect to each other. Accordingly, as these optical images LA pass through the λ/4 plate 24, circularly polarized light rotating in opposite directions can be output from each of the phase modulation regions 151 adjacent to each other. Thus, it is possible to electrically change an intensity ratio of left-handed circularly polarized light and right-handed circularly polarized light. Such a semiconductor light emitting element can be used, for example, as a light source for photonic quantum communication or quantum computers.

### Fourth Modification

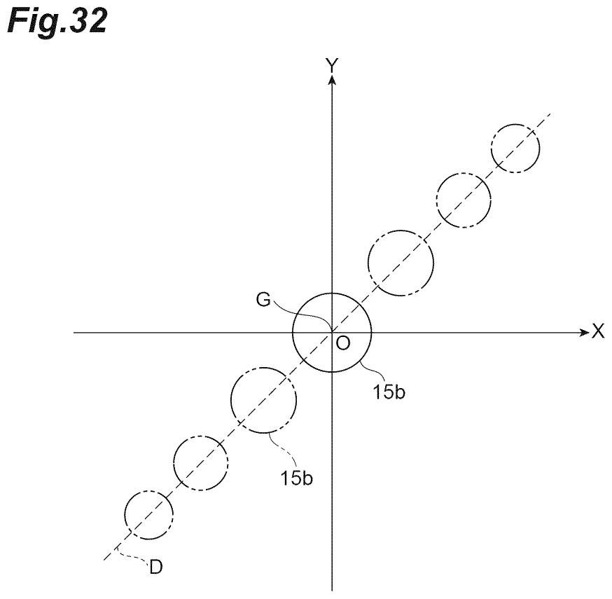

Areas of each of the plurality of different refractive index regions 15b in the cross-section perpendicular to the thickness direction of the phase modulation layer 15 may be set individually according to a predetermined optical image LA. In that case, since not only the phase but also the light intensity can be adjusted for each different refractive index region 15b, a degree of freedom in designing the optical image LA can be increased. FIG. 32 is an enlarged view of one unit constituent region R. In the example shown in the figure, an area of the different refractive index region 15b is largest when the centroid G of the different refractive index region 15b coincides with the lattice point O, and the area of the different refractive index region 15b becomes smaller as the centroid G of the different refractive index region 15b moves away from the lattice point O (that is, as the distance r(x, y) increases). In this way, the area of the different refractive index region 15b may be changed in accordance with a relative position of the centroid G of the different refractive index region 15b with respect to the lattice point O. Thus, it is possible to make the light intensity constant regardless of the phase distribution φ(x, y).

### Second Embodiment

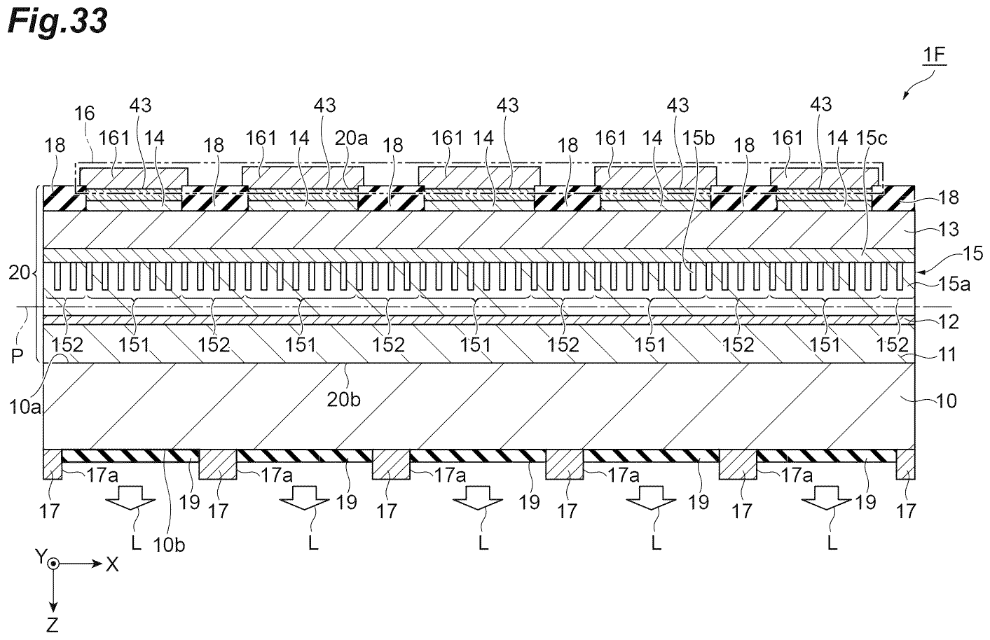

FIG. 33 is a cross-sectional view showing a stacked structure of a semiconductor light emitting element 1F according to a second embodiment. The semiconductor light emitting element 1F includes a light absorption layer 43 instead of the reflection reduction structure 41 of the above-described embodiment. The light absorption layer 43 is a reflection reduction structure according to the present embodiment, which is configured to reduce the reflection of the light emitted from each phase modulation region 151 at the electrode portion 16. The light absorption layer 43 is provided between the electrode portion 16 and both the active layer 12 and the phase modulation layer 15, and overlaps the plurality of phase modulation regions 151 when viewed from the stacking direction. The light absorption layer 43 includes a material having a higher light absorption property than the contact layer 14, and absorbs the light L2 (see FIG. 25) traveling from each phase modulation region 151 toward the electrode portion 16. However, the light absorption layer 43 is formed of a material that is conductive and does not interfere with carrier injection from the electrode portion 16 to the active layer 12. The light absorption layer 43 is provided in the semiconductor stack 20 and forms one layer of the semiconductor stack 20. In the present embodiment, the light absorption layer 43 is provided between the contact layer 14 and the electrode portion 16. The light absorption layer 43 has a light absorptance of more than 50% at the emission wavelength of the active layer 12. A thickness of the light absorption layer 43 is, for example, 100 nm or more.

As an example, when the emission wavelength of the active layer 12 is 940 nm (wavelength energy is 1.319 eV), the semiconductor substrate 10 is, for example, a GaAs substrate, and the contact layer 14 is, for example, a GaAs layer. In this case, the light absorption layer 43 includes at least one material selected from the group consisting of, for example, InAs, GaSb, InSb, InₓGa₁₋ₓAs (0.2≤x≤1), InₓGa₁₋ₓSb (0≤x≤1), GaAsₓSb₁₋ₓ (0≤x≤0.8), InAsₓSb₁₋ₓ (0≤x≤1), InAsₓP₁₋ₓ(0.1≤x≤1), GaPₓSb₁₋ₓ (0≤x≤0.5), InPₓSb₁₋ₓ (0≤x≤0.9), InₓGa₁₋ₓAs_{y}P_{1-y}(0≤x≤1, 0≤y≤1), and In_{1-x-y}AlₓGa_{y}As (0≤x≤1, 0≤y≤1).

As another example, when the emission wavelength of the active layer 12 is 640 nm (wavelength energy is 1.938 eV), the semiconductor substrate 10 is, for example, a GaAs substrate, and the contact layer 14 is, for example, a GaAs layer. In this case, the light absorption layer 43 includes at least one material selected from the group consisting of, for example, GaAs, InAs, InP, GaSb, InSb, InₓGa₁₋ₓAs (0≤x≤1), InₓGa₁₋ₓP (0.6≤x≤1), InₓGa₁₋ₓSb (0≤x≤1), GaAsₓSb₁₋ₓ (0≤x≤1), InAsₓSb₁₋ₓ (0≤x≤1), GaAsₓP₁₋ₓ (0.6≤x≤1), InAsₓP₁₋ₓ (0≤x≤1), GaPₓSb₁₋ₓ (0≤x≤0.7), InPₓSb₁₋ₓ (0≤x≤1), InₓGa₁₋ₓAs_{y}P_{1-y}(0≤x≤1, 0≤y≤1), and In_{1-x-y}AlₓGa_{y}As (0≤x≤1, 0≤y≤1).

As yet another example, when the emission wavelength of the active layer 12 is 1550 nm (wavelength energy is 0.800 eV), the semiconductor substrate 10 is, for example, an InP substrate, and the contact layer 14 is, for example, an In_{0.53}Ga_{0.47}As layer. In this case, the light absorption layer 43 includes at least one material selected from the group consisting of, for example, InAs, InSb, InₓGa₁₋ₓAs (0.6≤x≤1), InₓGa₁₋ₓSb (0.1≤x≤1), GaAsₓSb₁₋ₓ (0.1≤x≤0.4), InAsₓP₁₋ₓ (0≤x≤1), GaPₓSb₁₋ₓ (0.1≤x≤0.2), InPₓSb₁₋ₓ (0≤x≤0.7), InₓGa₁₋ₓAs_{y}P_{1-y}(0≤x≤1, 0≤y≤1), and In_{1-x-y}AlₓGa_{y}As (0≤x≤1, 0≤y≤1).

In the present embodiment, the semiconductor stack 20 is provided with the light absorption layer 43. In this way, the reflection reduction structure may include a structure that is provided between the electrode portion 16 and both the active layer 12 and the phase modulation layer 15, overlaps the plurality of phase modulation regions 151 when viewed from the stacking direction, and absorbs the light L2 traveling from each phase modulation region 151 toward the electrode portion 16. By absorbing the light L2 traveling from each phase modulation region 151 toward the electrode portion 16, reflection at the electrode portion 16 can be reduced. Accordingly, stray light can be effectively reduced.

As in the present embodiment, the absorbing structure may include the light absorption layer 43 provided in the semiconductor stack 20. For example, such a structure can absorb the light L2 traveling from each phase modulation region 151 toward the electrode portion 16.

As in the present embodiment, the light absorption layer 43 may be provided between the contact layer 14 and the electrode portion 16. In this case, the light L2 traveling from each phase modulation region 151 toward the electrode portion 16 can be effectively absorbed.

As in the present embodiment, the light absorption layer 43 may have a light absorptance of 50% or more at the emission wavelength of the active layer 12. In this case, the light traveling from each phase modulation region 151 toward the electrode portion 16 can be effectively absorbed.

### Fifth Modification

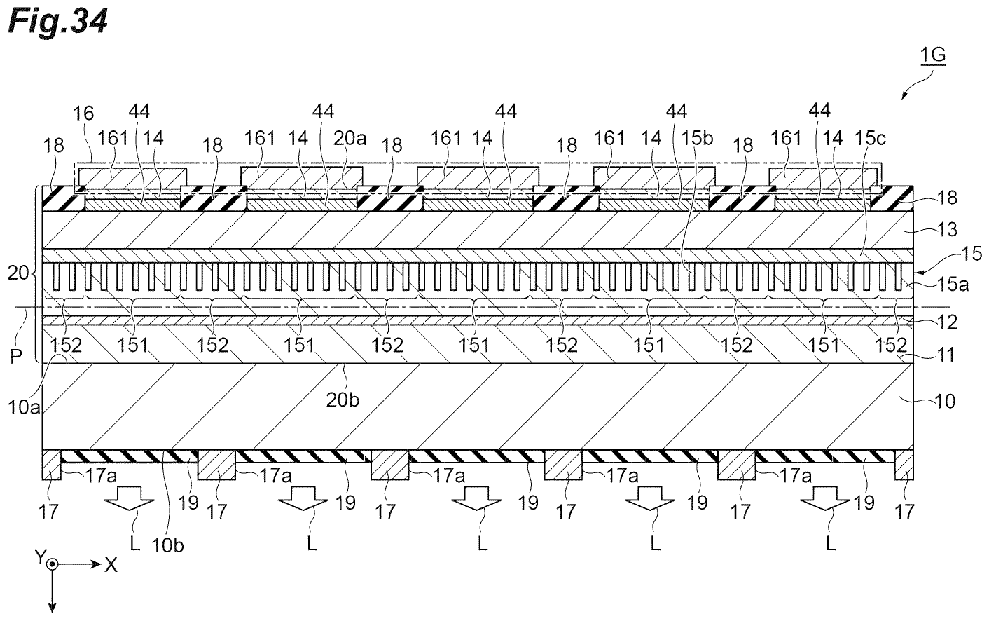

FIG. 34 is a cross-sectional view showing a stacked structure of a semiconductor light emitting element 1G as a fifth modification. The semiconductor light emitting element 1G differs from the second embodiment in the position at which the light absorption layer is provided. The semiconductor light emitting element 1G has a light absorption layer 44 instead of the light absorption layer 43 of the second embodiment. The light absorption layer 44 is provided between the cladding layer 13 and the contact layer 14. Also, the configuration of the light absorption layer 44, except for the position, is the same as that of the light absorption layer 43.

As in the present modification, the light absorption layer 44 may be provided between the cladding layer 13 and the contact layer 14. In this case, the light L2 (see FIG. 25) traveling from each phase modulation region 151 toward the electrode portion 16 can also be effectively absorbed.

### Sixth Modification

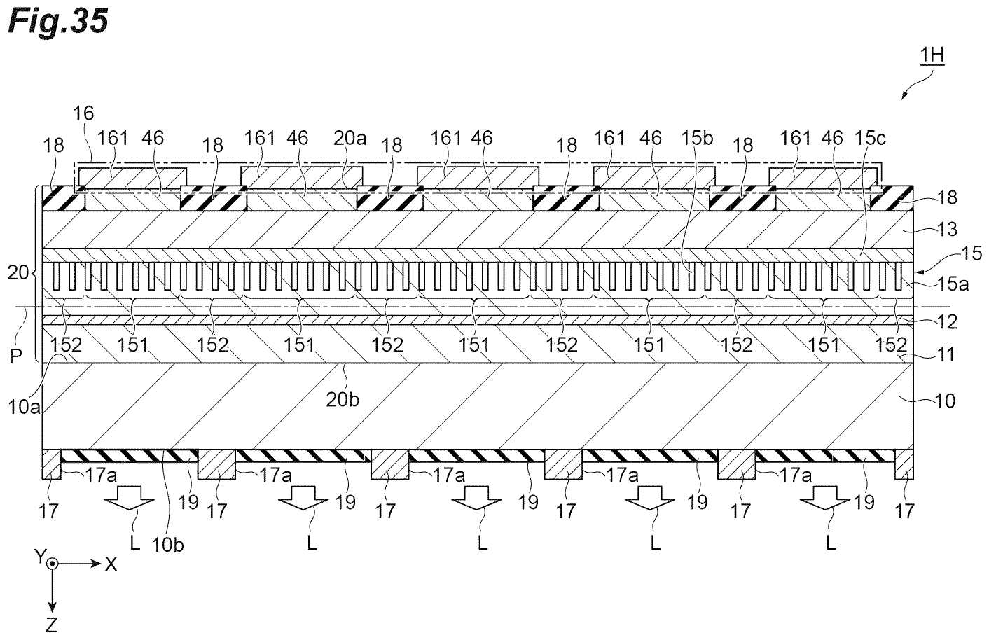

FIG. 35 is a cross-sectional view showing a stacked structure of a semiconductor light emitting element 1H as a sixth modification. The semiconductor light emitting element 1H differs from the second embodiment in that it has a contact layer 46 instead of the contact layer 14, and the contact layer 46 functions as the light absorption layer. That is, the semiconductor stack 20 of the present modification includes the contact layer 46 as a light absorption layer. A constituent material of the contact layer 46 is the same as that of the light absorption layer 43 of the second embodiment.

As in the present modification, the semiconductor stack 20 may include the contact layer 46 as a light absorption layer. In this case, the light L2 (see FIG. 25) traveling from each phase modulation region 151 toward the electrode portion 16 can also be effectively absorbed.

### Third Embodiment

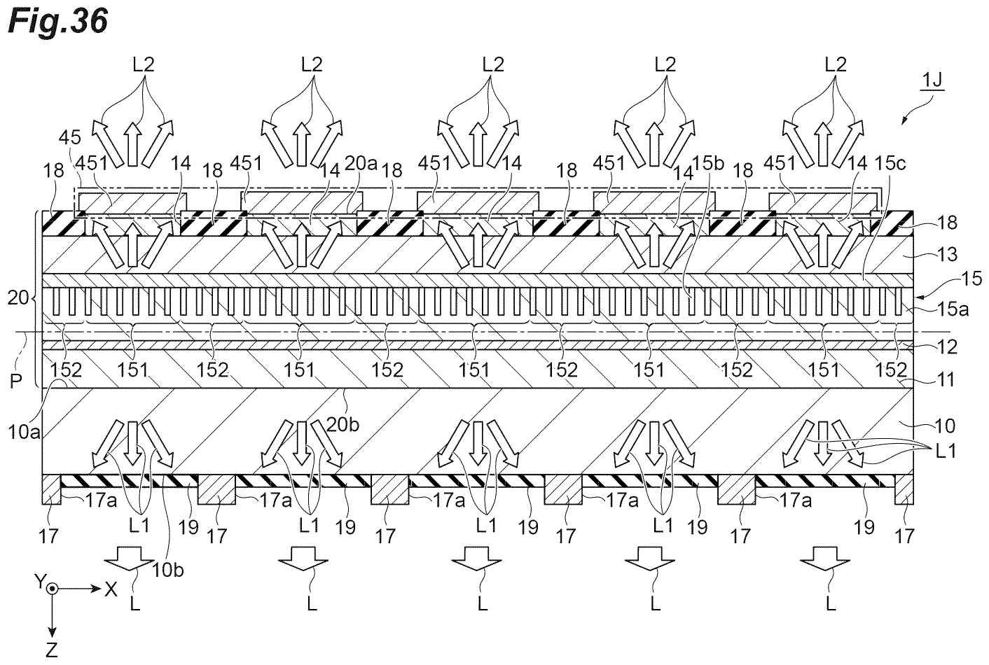

FIG. 36 is a cross-sectional view showing a stacked structure of a semiconductor light emitting element 1J according to a third embodiment of the present disclosure. The semiconductor light emitting element 1J does not have the reflection reduction structure 41 of the first embodiment. Alternatively, the semiconductor light emitting element 1J includes a transparent electrode portion 45 as a reflection reduction structure instead of the metal electrode portion 16. The transparent electrode portion 45 has a structure that transmits the light L2 from each phase modulation region 151. Specifically, the transparent electrode portion 45 has a light transmittance of 50% or higher at the emission wavelength of the active layer 12. The transparent electrode portion 45 includes a plurality of electrodes 451. Also, a configuration of the plurality of electrodes 451 is the same as that of the electrodes 161 of the first embodiment, except that they have light transmittance. As a constituent material of the transparent electrode portion 45, ITO, ZnO:Al (AZO), or ZnO:Ga (GZO) can be exemplified, for example.

As in the present embodiment, the reflection reduction structure may include a structure that transmits the light L2 from each phase modulation region 151 in the transparent electrode portion 45. The transparent electrode portion 45 transmits the light L2 from each phase modulation region 151, thereby reducing the reflection of the light L2. Accordingly, stray light can be effectively reduced. Also, a metal layer having a thickness that does not hinder the transmission (does not contribute to the reflection) may be provided between the contact layer 14 and the transparent electrode portion 45.

As in the present embodiment, the transparent electrode portion 45 may have a light transmittance of 50% or more at the emission wavelength of the active layer 12. In this case, the transparent electrode portion 45 can effectively transmit the light L2 from each phase modulation region 151.

The semiconductor light emitting element according to the present disclosure is not limited to the above-described embodiments, and various other modifications are possible. For example, the above-described embodiments may be combined with each other depending on a desired purpose and effects. That is, the semiconductor light emitting element may have at least two of the reflection reduction structure 41 of the first embodiment, the reflection reduction structure 42 of the first modification, the light absorption layer 43 of the second embodiment, the light absorption layer 44 of the fifth modification, the contact layer 46 of the sixth modification, and the transparent electrode portion 45 of the third embodiment. In this case, stray light can be further reduced.

Also, the reflection reduction structure that reduces the reflection of the light L2 emitted from each phase modulation region 151 is not limited to each of the embodiments and modifications described above, but may have other structures.

The semiconductor light emitting element according to the present disclosure is described as follows.

[1]A semiconductor light emitting element according to an aspect of the present disclosure includes a semiconductor stack, a first electrode portion, and a second electrode portion. The semiconductor stack has a stacked structure between a first surface and a second surface. The stacked structure includes an active layer and a phase modulation layer. The phase modulation layer has a plurality of phase modulation regions. The plurality of phase modulation regions are arranged along a virtual plane perpendicular to a thickness direction of the phase modulation layer and optically coupled to each other. Each of the plurality of phase modulation regions includes a base region and a plurality of different refractive index regions. The base region has a first refractive index. The plurality of different refractive index regions are provided in the base region, have a second refractive index different from the first refractive index, and are distributed two-dimensionally along the virtual plane. The first electrode portion faces the first surface of the semiconductor stack. The second electrode portion faces the second surface of the semiconductor stack. One or both of the first electrode portion and the second electrode portion include a plurality of electrodes that respectively overlap the plurality of phase modulation regions when viewed from a stacking direction of the semiconductor stack. The plurality of electrodes are electrically isolated from each other. Light output from the active layer resonates along the virtual plane in each of the plurality of phase modulation regions of the phase modulation layer. The resonant light is radiated from each of the plurality of phase modulation regions to an irradiated region located in a direction intersecting both the first surface and the second surface of the semiconductor stack via the second surface. The semiconductor light emitting element has a reflection reduction structure configured to reduce reflection of the light emitted from each phase modulation region on the first electrode portion.

The present inventors have tried and tested a structure that can reduce stray light and have found that, when an emission wavelength of the active layer is set to 940 nm, if an InGaAs layer of a certain thickness (for example, 500 nm) is provided between the first electrode portion, which is an electrode located on a side opposite to a light-exit surface, and a GaAs contact layer, the stray light can be significantly reduced. InGaAs has a relatively high light absorption property at a wavelength of 940 nm. In addition, since InGaAs is lattice-mismatched with GaAs, a surface of the InGaAs layer becomes a rough surface. From these facts, it is conceivable that the light emitted from the phase modulation layer through the side opposite to the light-exit surface is absorbed and scattered before it reaches the first electrode portion, thereby reducing reflection of the light on the first electrode portion, which leads to a reduction in the stray light. In other words, the reflection of the light on the first electrode portion is considered to be the cause of the stray light. Also, stray light does not occur in a type of semiconductor light emitting element in which the phase modulation layer is not divided into a plurality of phase modulation regions. Accordingly, it is inferred that the stray light is caused when light emitted from a certain phase modulation region and reflected by the first electrode portion leaks into light output from an adjacent phase modulation region. According to the semiconductor light emitting element according to [1] above, by providing the reflection reduction structure configured to reduce the reflection of the light emitted from each phase modulation region on the first electrode portion, stray light can be effectively reduced.

[2] In the semiconductor light emitting element according to [1] above, the reflection reduction structure may include a scattering structure that scatters the light traveling from each phase modulation region toward the first electrode portion. The scattering structure may be provided between the first electrode portion and both the active layer and the phase modulation layer, and may overlap the plurality of phase modulation regions when viewed from the stacking direction. By scattering the light traveling from each phase modulation region toward the first electrode portion, the reflection on the first electrode portion can be reduced. Accordingly, stray light can be effectively reduced.

[3] In the semiconductor light emitting element according to [2] above, the scattering structure may include an uneven structure formed on an interface between two adjacent layers in the semiconductor stack or on the first surface. For example, such a structure can scatter the light traveling from each phase modulation region toward the first electrode portion.

[4] In the semiconductor light emitting element according to [3] above, the semiconductor stack may include a cladding layer provided on the active layer and the phase modulation layer, and a contact layer provided on the cladding layer and adjacent to the cladding layer. The uneven structure may be formed at an interface between the cladding layer and the contact layer. In this case, the light traveling from each phase modulation region toward the first electrode portion can be effectively scattered.

[5] In the semiconductor light emitting element according to [3] or [4] above, the uneven structure may be caused by lattice mismatch in the semiconductor stack. In this case, the uneven structure can be easily formed.

[6] In the semiconductor light emitting elements according to [1] above, the reflection reduction structure may include an absorbing structure that is provided between the first electrode portion and both the active layer and the phase modulation layer, overlaps the plurality of phase modulation regions when viewed from the stacking direction, and absorbs the light traveling from each phase modulation region toward the first electrode portion. By absorbing the light traveling from each phase modulation region toward the first electrode portion, the reflection on the first electrode portion can be reduced. Accordingly, stray light can be effectively reduced.

[7] In the semiconductor light emitting element according to [6] above, the absorbing structure may include a light absorption layer provided in the semiconductor stack. For example, such a structure can absorb the light traveling from each phase modulation region toward the first electrode portion.

[8] In the semiconductor light emitting element according to [7] above, the semiconductor stack may include a cladding layer provided on the active layer and the phase modulation layer, and a contact layer provided on the cladding layer. The light absorption layer may be provided between the cladding layer and the contact layer, or between the contact layer and the first electrode portion. In this case, the light traveling from each phase modulation region toward the first electrode portion can be effectively absorbed.

[9] In the semiconductor light emitting element according to [7] above, the semiconductor stack may include a cladding layer provided on the active layer and the phase modulation layer, and a contact layer serving as a light absorption layer provided on the cladding layer. In this case, the light traveling from each phase modulation region toward the first electrode portion can be effectively absorbed.

[10] In the semiconductor light emitting elements according to [7] to [9] above, the light absorption layer may have a light absorptance of 50% or more at the emission wavelength of the active layer. In this case, the light traveling from each phase modulation region toward the first electrode portion can be effectively absorbed.

[11] In the semiconductor light emitting elements according to [1] to [10] above, the reflection reduction structure may include a structure that transmits light from each phase modulation region through the first electrode portion. By transmitting the light from each phase modulation region toward the first electrode portion through the first electrode portion, reflection of the light can be reduced. Thus, stray light can be effectively reduced.

[12] In the semiconductor light emitting element according to [11] above, the first electrode portion may have a light transmittance of 50% or more at the emission wavelength of the active layer. In this case, the light traveling from each phase modulation region toward the first electrode portion can be effectively transmitted through the first electrode portion.

What is claimed is:

1. A semiconductor light emitting element comprising:
a semiconductor stack that includes a stacked structure including an active layer and a phase modulation layer between a first surface and a second surface, the phase modulation layer including a plurality of phase modulation regions arranged along a virtual plane perpendicular to a thickness direction of the phase modulation layer and optically coupled to each other, each of the plurality of phase modulation regions including a base region having a first refractive index, and a plurality of different refractive index regions which are provided in the base region, have a second refractive index different from the first refractive index, and are distributed two-dimensionally along the virtual plane;
a first electrode portion facing the first surface of the semiconductor stack; and
a second electrode portion facing the second surface of the semiconductor stack,
wherein
one or both of the first electrode portion and the second electrode portion include a plurality of electrodes that respectively overlap the plurality of phase modulation regions when viewed from a stacking direction of the semiconductor stack, the plurality of electrodes being electrically isolated from each other,
light output from the active layer resonates along the virtual plane in each of the plurality of phase modulation regions of the phase modulation layer, and is radiated from each of the plurality of phase modulation regions to an irradiated region located in a direction intersecting both the first surface and the second surface of the semiconductor stack via the second surface, and
the semiconductor light emitting element has a reflection reduction structure configured to reduce reflection of the light emitted from each phase modulation region on the first electrode portion.

2. The semiconductor light emitting element according to claim 1, wherein the reflection reduction structure includes a scattering structure that is provided between the first electrode portion and both the active layer and the phase modulation layer, overlaps the plurality of phase modulation regions when viewed from the stacking direction, and scatters the light traveling from each phase modulation region toward the first electrode portion.

3. The semiconductor light emitting element according to claim 2, wherein the scattering structure includes an uneven structure formed at an interface between two adjacent layers in the semiconductor stack or on the first surface.

4. The semiconductor light emitting element according to claim 3, wherein
the semiconductor stack includes a cladding layer provided on the active layer and the phase modulation layer, and a contact layer provided on the cladding layer and adjacent to the cladding layer, and
the uneven structure is formed at an interface between the cladding layer and the contact layer.

5. The semiconductor light emitting element according to claim 3, wherein the uneven structure is caused by lattice mismatch in the semiconductor stack.

6. The semiconductor light emitting element according to claim 1, wherein the reflection reduction structure includes an absorbing structure that is provided between the first electrode portion and both the active layer and the phase modulation layer, overlaps the plurality of phase modulation regions when viewed from the stacking direction, and absorbs the light from each phase modulation region toward the first electrode portion.

7. The semiconductor light emitting element according to claim 6, wherein the absorbing structure includes a light absorption layer provided in the semiconductor stack.

8. The semiconductor light emitting element according to claim 7, wherein
the semiconductor stack includes a cladding layer provided on the active layer and the phase modulation layer, and a contact layer provided on the cladding layer, and
the light absorption layer is provided between the cladding layer and the contact layer, or between the contact layer and the first electrode portion.

9. The semiconductor light emitting element according to claim 7, wherein the semiconductor stack includes a cladding layer provided on the active layer and the phase modulation layer, and a contact layer as the light absorption layer provided on the cladding layer.

10. The semiconductor light emitting element according to claim 7, wherein the light absorption layer has a light absorptance of 50% or more at an emission wavelength of the active layer.

11. The semiconductor light emitting element according to claim 1, wherein the reflection reduction structure includes a structure that transmits the light from each phase modulation region through the first electrode portion.

12. The semiconductor light emitting element according to claim 11, wherein the first electrode portion has a light transmittance of 50% or more at an emission wavelength of the active layer.
